(19) United States
(12) Patent Application Publication
(10) Pub. No.: US 2026/0164893 A1
(43) Pub. Date: Jun. 11, 2026

(54) DISPLAY DEVICE, METHOD OF MANUFACTURING THE DISPLAY DEVICE, AND ELECTRONIC DEVICE

(71) Applicant: Samsung Display Co., Ltd., Yongin-Si (KR)

(72) Inventors: Il Sup KIM, Yongin-si (KR); In Soo PARK, Yongin-si (KR)

(21) Appl. No.: 19/288,178

(22) Filed: Aug. 1, 2025

(30) Foreign Application Priority Data
Dec. 11, 2024 (KR) 10-2024-0183979

(51) Int. Cl. H10H 29/80; H10H 29/01

(52) U.S. Cl. CPC H10H 29/8321; H10H 29/012; H10H 29/8323

(57) ABSTRACT

According to embodiments of the disclosure, a display device, a method of manufacturing the display device, and an electronic device are provided. The display device may include: a light-emitting element including an anode electrode disposed on a substrate, a light-emitting structure electrically connected to the anode electrode, and a cathode electrode electrically connected to the light-emitting structure; and a cover layer disposed on the anode electrode. The anode electrode may include a first end, the cover layer may include a second end, and the first end and the second end may have side surfaces in parallel planes.

### CROSS-REFERENCE TO RELATED APPLICATION

The present application claims priority, under 35 U.S.C. § 119(a), to Korean Patent Application No. 10-2024-0183979 filed on Dec. 11, 2024 in the Korean Intellectual Property Office, the entire disclosure of which is incorporated herein by reference.

### BACKGROUND

### 1. Technical Field

Embodiments of the present disclosure relate to a display device, a method of manufacturing the display device, and an electronic device.

### 2. Related Art

With the recent increase in interest in information display, research and development on display devices are continuously being conducted.

A display device may include sub-pixels including organic light-emitting diodes (OLED). The organic light-emitting diodes are active light-emitting display devices that not only have a wide viewing angle and excellent contrast, but also can be driven at low voltages, and have the advantage of being lightweight and fast in response speed.

The organic light-emitting diode may include a hole transport unit, an electron transport unit, and a light-emitting layer between the hole transport unit and the electron transport unit. Holes provided from the hole transport unit and electrons provided from the electron transport unit may recombine in the light-emitting layer to produce excitons. The generated excitons change from the excited state to the ground state, and light may be generated.

The layers forming the display device are manufactured through various processes. In order to reduce manufacturing costs, there is a need to improve process convenience, and it may be desirable to reduce the risk of excessive formation of unintended structures during the process

### SUMMARY

An aspect of the present disclosure is to provide a display device in which a process procedure may be simplified and a process cost may be reduced, a method of manufacturing the display device, and an electronic device.

An aspect of the present disclosure is to provide a display device in which a risk that an unintended structure is excessively formed may be reduced and the operation reliability characteristics may be improved, a method of manufacturing the display device, and an electronic device.

According to an embodiment of the present disclosure, a display device may include: a light-emitting element including an anode electrode disposed on a substrate, a light-emitting structure electrically connected to the anode electrode, and a cathode electrode electrically connected to the light-emitting structure; and a cover layer disposed on the anode electrode. The anode electrode may include a first end, the cover layer may include a second end, and the first end and the second end may have side surfaces in parallel planes.

In an embodiment, the display device may further include a lower structure that is disposed between the substrate and the light-emitting element and is covered by the anode electrode.

In an embodiment, the display device may further include sub-pixels each including the light-emitting element and the cover layer; and a pixel circuit disposed on the substrate and electrically connected to the anode electrode. The lower structure may include a conductive layer, a reflective layer on the conductive layer, and a step-forming layer on the reflective layer. The conductive layer may be electrically connected to the pixel circuit. The reflective layer may reflect light in a display direction of the display device. The step-forming layer may have different thicknesses in different sub-pixels.

In an embodiment, the lower structure may have a trapezoidal cross-section, a lower surface of the reflective layer may contact the conductive layer, and an upper surface of the reflective layer may contact the step-forming layer.

In an embodiment, the anode electrode may cover a side surface of each of the conductive layer, the reflective layer, and the step-forming layer. The anode electrode disposed on an upper surface of the step-forming layer may cover an entire upper surface of the step-forming layer such that the anode electrode is between the light-emitting structure and the upper surface of the lower structure.

In an embodiment, the cover layer may cover a first portion of the anode electrode that includes a side surface of the lower structure but does not cover a second portion of the anode electrode disposed on the top surface of the lower structure.

In an embodiment, the display device may further include an insulating layer covering a portion of the cover layer on the side surface of the lower structure while not covering the second portion of the anode electrode, and including an inorganic material; and an intermediate layer disposed adjacent to the lower structure to offset a step formed by the lower structure.

In an embodiment, the anode electrode may include indium tin oxide (ITO) or titanium nitride (TiN). The insulating layer may include silicon nitride (SixNy). The intermediate layer may include an oxide material.

In an embodiment, the display device may further include a pixel defining layer disposed on the intermediate layer and including a first pixel defining layer having a first width and a second pixel defining layer having a second width greater than the first width and disposed on the first pixel defining layer.

In an embodiment, the cover layer may be in contact with the anode electrode but not with a side surface of the first end of the anode electrode. The side surface of the first end may be coplanar with a side surface of the second end of the cover layer.

In an embodiment, the second end of the cover layer may overlap the first end of the anode electrode.

In an embodiment, the cover layer may include an inorganic oxide. The cover layer may have a thickness in a range of 500 to 1000 Angstroms.

According to an embodiment of the present disclosure, a method of manufacturing a display device may include: forming a base anode electrode on a substrate and on a lower structure on the substrate; patterning a cover layer covering the base anode electrode and removing part of the cover layer to expose at least a portion of the base anode electrode; forming an anode electrode by removing at least the portion of the base anode electrode using the cover layer as an etch mask; and removing a residue portion that forms at an end portion of the cover layer, the reside portion including a same material as the base anode electrode.

In an embodiment, the method may further include patterning the lower structure including a conductive layer, a reflective layer on the conductive layer, and a step-forming layer on the reflective layer. The forming of the base anode electrode may include covering a side surface of the lower structure by the base anode electrode. The lower structure may have a trapezoidal cross-section.

In an embodiment, the pattering of the cover layer may include: forming a base cover layer covering the anode electrode and including an oxide; patterning a photoresist layer on the base cover layer; and dry etching the base cover layer using the photoresist layer as an etching mask. The base cover layer may be formed by an atomic layer deposition (ALD) process.

In an embodiment, the method may further include, after patterning the cover layer, performing an ashing process to remove the photoresist layer. The patterning of the cover layer may include: forming a side end of the cover layer; and exposing at least a portion of the base anode electrode with the cover layer in place.

In an embodiment, the forming of the anode electrode may include exposing a side surface at an end of the anode electrode while covering un upper surface of the anode electrode with the cover layer.

In an embodiment, in the forming of the anode electrode, the upper surface of the cover layer used as a hard etching mask for the anode electrode may be exposed.

In an embodiment, after providing the anode electrode, the cover layer may cover the entire anode electrode except for the side surface at the end.

In an embodiment, the residue portion may include a same material as the anode electrode. The residue portion may cover a side surface at an end of the cover layer.

In an embodiment, a thickness of the residue portion may be determined based on a thickness of the cover layer used as a hard etching mask for the anode electrode.

In an embodiment, the method may further include fixing the substrate by the chuck while forming the anode electrode. The cover layer may include an inorganic oxide. The chuck may be heated about to 80 degrees.

In an embodiment, in the removing of the residue portion, a wet cleaning method using Diluted HF (DHF) may be performed. The residue portion may have a first etch ratio for the cover layer and a second etch ratio smaller than the first etch ratio for the anode electrode.

In an embodiment, the method may further include: forming an insulating layer covering a side end of each of the cover layer and the anode electrode; and after forming a base intermediate layer, polishing the base intermediate layer to a polishing stopper plane formed in a region where the uppermost surface of the insulating layer is exposed to form an intermediate layer flattening lower steps.

In an embodiment, the method may further include: patterning a pixel defining layer on the intermediate layer; exposing at least a portion of the anode electrode; forming a light-emitting structure electrically connected to the anode electrode; and forming a cathode electrode electrically connected to the light-emitting structure.

According to an embodiment of the present disclosure, an electronic device may include: a processor providing input image data; a display device displaying an image based on the input image data; and a power supply supplying power to the display device. The display device may include: a light-emitting element including an anode electrode disposed on a substrate, a light-emitting structure electrically connected to the anode electrode, and a cathode electrode electrically connected to the light-emitting structure; and a cover layer disposed on the anode electrode. The anode electrode may include a first end, the cover layer may include a second end, and the first end and the second end may have side surface in parallel planes.

### BRIEF DESCRIPTION OF THE DRAWINGS

FIG. 1 is a schematic plan view illustrating a display device according to an embodiment.

FIG. 2 is a schematic exploded perspective view illustrating a display device according to an embodiment.

FIG. 3 is a schematic plan view illustrating a pixel according to an embodiment.

FIG. 4 is a schematic plan view illustrating a pixel according to another embodiment.

FIG. 5 is a schematic plan view illustrating a pixel according to another embodiment.

FIGS. 6 and 7 are schematic cross-sectional views illustrating a display device according to an embodiment.

FIG. 8 is a diagram illustrating an area where an anode electrode and a cover layer are adjacent to each other according to an embodiment.

FIG. 9 is a schematic cross-sectional view illustrating a light-emitting structure according to an embodiment.

FIG. 10 is a schematic cross-sectional view illustrating a light-emitting structure according to an embodiment.

FIGS. 11 to 20 are schematic cross-sectional views at each process stage illustrating a method of manufacturing a display device according to an embodiment.

FIG. 21 is a block diagram illustrating an embodiment of an electronic device.

FIG. 22 is a perspective view illustrating an example electronic device of FIG. 21 in accordance with an embodiment.

FIG. 23 is a view illustrating a head-mounted display device of FIG. 22 on a user.

FIGS. 24 to 28 are schematic diagrams illustrating examples of display device according to an embodiment.

### DETAILED DESCRIPTION

The present disclosure may make various modifications and take various forms, and specific embodiments will be illustrated in the drawings and described in detail in the text. It is to be understood, however, that this disclosure is not intended to be limited to the particular form of disclosure, but is to cover all modifications, equivalents, and alternatives falling within the spirit and scope of the disclosure.

The terms first, second, etc. may be used to describe various components, but the components should not be limited by the terms. The above terms are used only for the purpose of distinguishing one component from another. For example, a first component may be named a second component, and similarly, a second component may also be named a first component, without departing from the scope of the present disclosure. The singular forms “a”, “an” and “the” include plural references unless the context clearly requires otherwise.

In this disclosure, the terms “comprise” or “have” and the like are intended to designate the presence of a feature, number, step, operation, component, part, or combination thereof described in the specification, and should not be understood to preclude the presence or possibility of addition of one or more other features, numbers, steps, operations, components, parts, or combinations thereof. Also, when a portion of a layer, film, region, plate, or the like is “on” another portion, this includes not only the case where it is “directly on” the other portion but also the case where there is another portion in the middle. Note that, in the present specification, when a portion of a layer, a film, a region, a plate, or the like is formed on another portion, the formed direction is not limited to an upper direction but includes a side or a lower direction. Conversely, if a part of a layer, film, area, plate, etc. is “below” another part, this includes not only the case where the other part is “right below” but also the case where there is another part in the middle.

The present disclosure relates to a display device, a method for manufacturing the display device, and an electronic device. Hereinafter, a display device, a method of manufacturing a display device, and an electronic device according to an embodiment will be described with reference to the accompanying drawings.

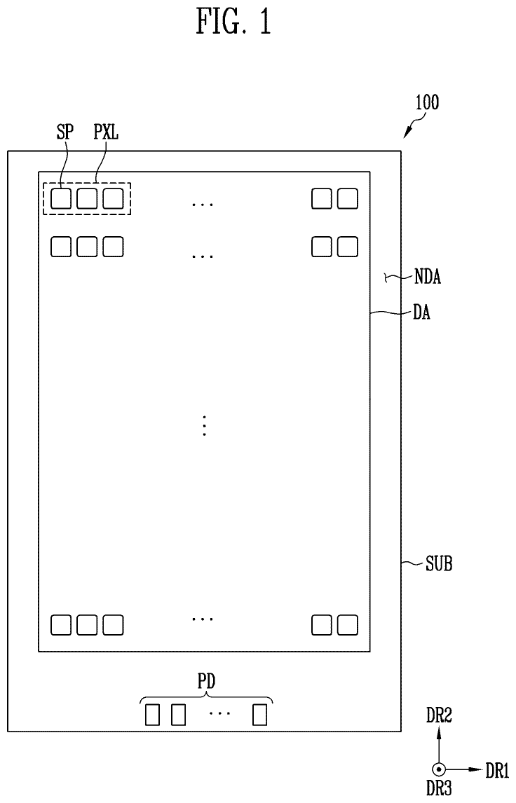

FIG. 1 is a schematic plan view illustrating a display device 100 according to an embodiment.

Referring to FIG. 1, the display device 100 according to an embodiment may emit light.

The display device 100 may include a display area DA and a non-display area NDA. The display device 100 may display an image through the display area DA. The non-display area NDA may be arranged around the display area DA.

The display device 100 may include a substrate SUB, sub-pixels SP, and pads PD.

The display device 100 may be applied to various electronic devices. For example, when the display device 100 is used as a display screen of a Head Mounted Display (HMD), a Virtual Reality (VR) device, a Mixed Reality (MR) device, an Augmented Reality (AR) device, or the like, the display device 100 may be located very close to the user's eyes. In this case, the sub-pixels SP with a relatively high degree of integration are required. In order to increase the degree of integration of the sub-pixels SP, the substrate SUB may be provided as a silicon substrate. The sub-pixels SP may be formed on the substrate SUB which is a silicon substrate. The display device 100 including a plurality of layers formed on the substrate SUB that is a silicon substrate may be referred to as an OLED on silicon (OLEDoS) display device.

The sub-pixels SP may be disposed in the display area DA on the substrate SUB. The sub-pixels SP may be arranged in a matrix form in a first direction DR1 and a second direction DR2 intersecting the first direction DR1. However, embodiments are not limited thereto. For example, the sub-pixels SP may be arranged in a zigzag shape in the first direction DR1 and the second direction DR2. For example, the sub-pixels SP may be disposed in PENTILE™ form. The first direction DR1 may be a row direction and the second direction DR2 may be a column direction.

The plane defined herein may be defined with reference to a plane in which the substrate SUB is disposed, as a direction extending in the first direction DR1 and the second direction DR2. According to an embodiment, a third direction DR3 may be a thickness direction of the substrate SUB, and the third direction DR3 may also be a light emission direction of the display device 100.

The sub-pixels SP may have various shapes in a plan view, and the shape of the sub-pixels SP is not limited to a specific example.

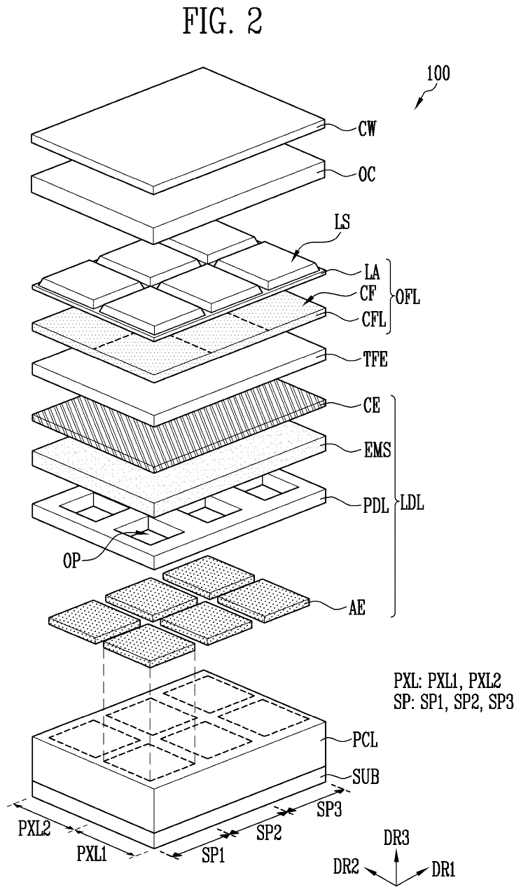

Each of the sub-pixels SP may include at least one light-emitting element LD (refer to FIG. 2) configured to generate light. Accordingly, each of the sub-pixels SP may generate light of a particular color, such as red, green, blue, cyan, magenta, yellow, or the like. Two or more of the sub-pixels SP may form a pixel PXL. For example, as shown in FIG. 1, three sub-pixels SP may form a pixel PXL.

Hereinafter, an embodiment will be described in which the sub-pixels SP include a first sub-pixel SP1 providing light of a first color (for example, red), a second sub-pixel SP2 providing light of a second color (for example, green), and a third sub-pixel SP3 providing light of a third color (for example, blue).

According to an embodiment, the first sub-pixel SP1 may be a red pixel, and may provide light in a wavelength band of 600 nm to 750 nm. The second sub-pixel SP2 may be a green pixel, and may provide light in a wavelength band of 480 nm to 560 nm. The third sub-pixel SP3 may be a blue pixel and may provide light in a wavelength band of 370 nm to 460 nm.

In the non-display area NDA on the substrate SUB, a component for controlling the sub-pixels SP may be disposed. For example, wirings connected to the sub-pixels SP (for example, gate lines and data lines for driving the sub-pixel SP, or the like) may be disposed in the non-display area NDA. In addition, a gate driver, a data driver, a voltage generator, a controller, a temperature sensor, and the like for obtaining driving signals supplied to the sub-pixels SP may be integrated in the non-display area NDA of the display device 100. However, the present disclosure is not limited thereto.

The pads PD may be disposed in the non-display area NDA on the substrate SUB. The pads PD may be electrically connected to the sub-pixels SP through the wirings. For example, the pads PD may be connected to the sub-pixels SP via the data lines.

The pads PD may interface components in the display area DA and the non-display area NDA to other components of the display device 100. In some embodiments, voltages and signals necessary for operation of components included in the display device 100 may be provided from a driver integrated circuit through the pads PD. For example, the data lines may be electrically connected to the driver integrated circuit via the pads PD. For example, a power supply voltage for driving the sub-pixels SP may be received from the driver integrated circuit via the pads PD. For example, a gate control signal for controlling the gate driver may be transmitted from the driver integrated circuit to the gate driver via the pads PD.

In some embodiments, a circuit board may be electrically connected to the pads PD using a conductive adhesive such as an anisotropic conductive film. In this case, the circuit board may be a flexible circuit board (FPCB) or a flexible film having a flexible material. The driver integrated circuit may be mounted on the circuit board and electrically connected to the pads PD.

In some embodiments, the display area DA may have various shapes. The display area DA may have a closed loop shape including straight and/or curved sides. For example, the display area DA may have shapes such as a polygon, a circle, a semicircle, an ellipse, or the like.

In some embodiments, the display device 100 may have a flat display surface. In some embodiments, the display device 100 may have at least partially rounded display surface. In some embodiments, the display device 100 may be bendable, foldable, or rollable. In such cases, the display device 100 and/or the substrate SUB may include materials having a flexible property.

FIG. 2 is a schematic exploded perspective view of the display device 100 according to an embodiment. In FIG. 2, a portion of the display device 100 corresponding to two pixels PXL1 and PXL2 among the pixels PXL is schematically illustrated for clarity and concise description. A portion of the display device 100 corresponding to the remaining pixels may be similarly configured.

Referring to FIG. 2, each of the first and second pixels PXL1 and PXL2 may include the first to third sub-pixels SP1 to SP3. However, embodiments are not limited thereto. For example, each of the first and second pixels PXL1 and PXL2 may include four sub-pixels, or may include two sub-pixels.

In FIG. 2, the first to third sub-pixels SP1 to SP3 are illustrated as having square shapes and having a same size in the first and second directions DR1 and DR2. However, embodiments are not limited thereto. The first to third sub-pixels SP1 to SP3 may be modified to have various shapes, and may have different shapes from one another.

The display device 100 may include the substrate SUB, a pixel circuit layer PCL, a light-emitting element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In some embodiments, the substrate SUB may include a glass substrate. In some embodiments, the substrate SUB may include a polyimide (PI) substrate.

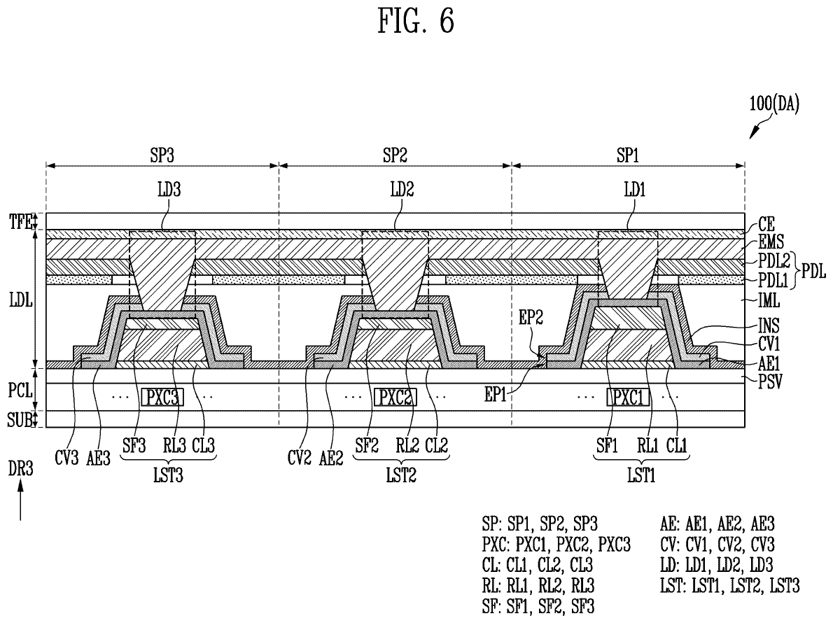

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least some of circuit elements, wirings, or the like. The conductive patterns may include a variety of conductive materials, and embodiments are not limited to specific examples. The circuit elements may include a pixel circuit PXC (refer to FIG. 6) of each of the first to third sub-pixels SP1 to SP3. The pixel circuit may include transistors and one or more capacitors.

The light-emitting element layer LDL may include anode electrodes AE, a pixel defining layer PDL, a light-emitting structure EMS, and a cathode electrode CE.

The anode electrodes AE may be disposed on the pixel circuit layer PCL. The anode electrodes AE may be electrically connected to the circuit elements of the pixel circuit layer PCL.

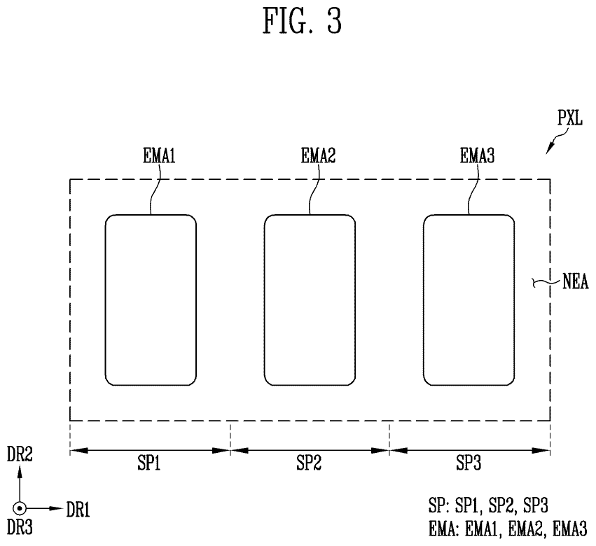

The pixel defining layer PDL may be disposed on the anode electrodes AE. The pixel defining layer PDL may include an opening OP exposing a portion of each of the anode electrodes AE. The opening OP of the pixel defining layer PDL may be understood as emission areas EMA (refer to FIG. 3) respectively corresponding to the first to third sub-pixels SP1 to SP3.

The light-emitting structure EMS may be disposed on the anode electrodes AE exposed by the opening OP of the pixel defining layer PDL. The light-emitting structure EMS may include a light-emitting layer EML configured to generate light (refer to FIG. 10), an electron transport unit ETU configured to transport electrons (refer to FIG. 10), a hole transport unit HTU configured to transport holes (refer to FIG. 10), and the like.

In some embodiments, the light-emitting structure EMS may fill the opening OP of the pixel defining layer PDL, and may be disposed entirely on top of the pixel defining layers PDL. In other words, the light-emitting structure EMS may extend over the first to third sub-pixels SP1 to SP3. In this case, at least some of the layers in the light-emitting structure EMS may break or bend at boundaries between the first to third sub-pixels SP1 to SP3.

The cathode electrode CE may be disposed on the light-emitting structure EMS. The cathode electrode CE may extend over the first to third sub-pixels SP1 to SP3. As such, the cathode electrode CE may be provided as a common electrode for the first to third sub-pixels SP1 to SP3.

The cathode electrode CE may be a thin metal layer having a thickness sufficient to transmit light emitted from the light-emitting structure EMS. The cathode electrode CE may supply a cathode voltage to the light-emitting structure EMS.

The cathode electrode CE may include a metallic material or a transparent conductive material to be thin. In some embodiments, a cathode electrode CE may include at least one of a variety of transparent conductive materials, such as Indium Tin Oxide (ITO), Indium Zinc Oxide (IGZO), Indium Gallium Zinc Oxid (IGZO) Aluminum Zinc Oxide (AZO), Indium Tin Zinc Oxide (ITZO), Zinc Oxide (ZnO), or Tin Oxide (SnO2). In some embodiments, the cathode electrode CE may include at least one of silver (Ag), magnesium (Mg), and mixtures thereof. However, the material of the cathode electrode CE is not limited thereto.

One of the anode electrodes AE, a portion of the light-emitting structure EMS which overlaps one of the anode electrode AE, and a portion of the cathode electrode CE which overlaps the portion of the light-emitting structure EMS may form a light-emitting element LD. In other words, the light-emitting elements of the first to third sub-pixels SP1 to SP3 may each include a anode electrode AE, the portion of the light-emitting structure EMS overlapping therewith, and the portion of the cathode electrode CE overlapping therewith. In each of the first to third sub-pixels SP1 to SP3, holes injected from the anode electrode AE and electrons injected from the cathode electrode CE are transported into the light-emitting layer EML of the light-emitting structure EMS to form excitons, and light may be generated when the excitons are transited from the excited state to the ground state. The luminance of light may be determined by the amount of current flowing through the light-emitting layer EML. The wavelength range of the generated light may be determined depending on the configuration of the light-emitting layer EML.

The encapsulation layer TFE may be disposed on the cathode electrode CE. The encapsulation layer TFE may cover the light-emitting element layer LDL and the pixel circuit layer PCL. The encapsulation layer TFE may prevent oxygen and/or moisture or the like from reaching the light-emitting element layer LDL. In some embodiments, the encapsulation layer TFE may include a structure in which one or more inorganic films and one or more organic films are alternately stacked. For example, the inorganic film may include silicon nitride, silicon oxide, silicon oxynitride (SixOyNz), or the like. For example, the organic film may include an organic insulating material such as an acrylic resin, an epoxy resin, a phenol resin, a polyamide resin, a polyimide resin, an unsaturated polyester resin, a polyphenylenether resin, a polymethylenesulfide resin, or benzocyclobutene (BCB). However, the materials of the organic film and the inorganic film of the encapsulation layer TFE are not limited thereto.

The optical functional layer OFL may be disposed on the encapsulation layer TFE. The optical functional layer OFL may include a color filter layer CFL and a lens array LA.

The color filter layer CFL is disposed between the encapsulation layer TFE and the lens array LA. The color filter layer CFL may filter the light emitted from the light-emitting structure EMS to selectively output light of a wavelength range or color corresponding to each sub-pixel. The color filter layer CFL may include color filters CF respectively corresponding to the first to third sub-pixels SP1 to SP3, each of which is capable of passing light in the wavelength range corresponding to the sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. At least one or more of the color filters CF may be omitted depending on the light emitted from the light-emitting structure EMS of each sub-pixel.

The lens array LA may be disposed on the color filter layer CFL. The lens array LA may include lenses LS respectively corresponding to the first to third sub-pixels SP1 to SP3. Each of the lenses LS may output light emitted from the light-emitting structure EMS in the intended path, thereby improving the light exit efficiency. The lens array LA may have a relatively high refractive index. For example, the lens array LA may have a higher refractive index than the overcoat layer OC. In some embodiments, the lenses LS may include an organic material. In some embodiments, the lenses LS may include an acrylic material. However, the material of the lenses LS is not limited thereto.

The overcoat layer OC may be disposed on the lens array LA. The overcoat layer OC may cover the optical functional layer OFL, the encapsulation layer TFE, the light-emitting structure EMS, and/or the pixel circuit layer PCL. The overcoat layer OC may include a variety of materials suitable for protecting the underlying layers thereof from foreign materials such as dust, moisture, or the like. For example, the overcoat layer OC may include at least one of an inorganic insulating film and an organic insulating film. For example, the overcoat layer OC may include, but is not limited to, epoxy. The overcoat layer OC may have a lower refractive index than the lens array LA.

The cover window CW may be disposed on the overcoat layer OC. The cover window CW may protect lower layers underneath. The cover window CW may have a higher refractive index than the overcoat layer OC. The cover window CW may include glass, but embodiments are not limited thereto. For example, the cover window CW may be an encapsulation glass configured to protect components disposed underneath. In some embodiments, the cover window CW may be omitted.

FIG. 3 is a schematic plan view illustrating pixels PXL according to an embodiment.

Referring to FIG. 3, the pixel PXL may include sub-pixels SP arranged in the first direction DR1. For example, the sub-pixels SP may include the first sub-pixel SP1, the second sub-pixel SP2, and the third sub-pixel SP3 arranged in the first direction DR1. Emission areas EMA may include first to third emission areas EMA1 to EMA3.

The first sub-pixel SP1 may include the first emission area EMA1 and a non-emission area NEA around the first emission area EMA1. The second sub-pixel SP2 may include the second emission area EMA2 and the non-emission area NEA around the second emission area EMA2. The third sub-pixel SP3 may include the third emission area EMA3 and the non-emission area NEA around the third emission area EMA3.

The first emission area EMA1 may be an area where light is emitted from a portion of the light-emitting structure EMS corresponding to the first sub-pixel SP1 (for example, the first light-emitting structure EMA1). The second emission area EMA2 may be an area where light is emitted from a portion of the light-emitting structure EMS corresponding to the second sub-pixel SP2 (for example, the second light-emitting structure EMA2). The third emission area EMA3 may be an area where light is emitted from a portion of the light-emitting structure EMS corresponding to the third sub-pixel SP3 (for example, the third light-emitting structure EMA3). As described with reference to FIG. 2, each emission area may be understood as the opening OP of the pixel defining layer PDL corresponding to each of the first sub-pixel SP1, the second sub-pixel SP2, and the third sub-pixel SP3.

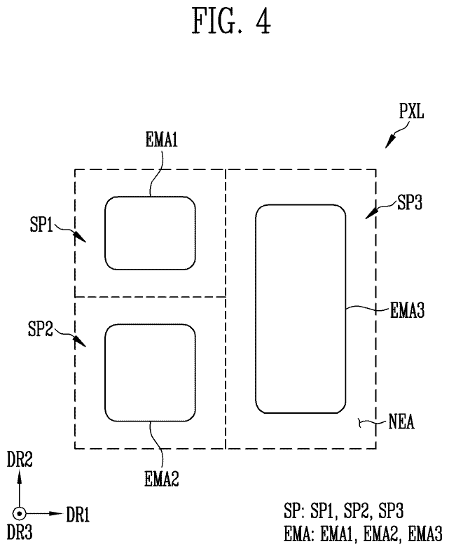

FIG. 4 is a schematic plan view illustrating the pixels PXL according to another embodiment.

Referring to FIG. 4, the first sub-pixel SP1 and the second sub-pixel SP2 may be disposed in the second direction DR2. The third sub-pixel SP3 may be disposed in the first direction DR1 with respect to each of the first and second sub-pixels SP1 and SP2.

The second sub-pixel SP2 may have an area greater than that of the first sub-pixel SP1, and the third sub-pixel SP3 may have an area greater than that of the second sub-pixel SP2. Accordingly, the second emission area EMA2 may have an area greater than that of the first emission area EMA1, and the third light-emitting region EMA3 may have an area greater than that of the second emission area EMA2. However, embodiments are not limited thereto. For example, the first and second sub-pixels SP1, SP2 may have substantially the same area as each other, and the third sub-pixel SP3 may have a greater area than each of the first and second sub-pixels SP1 and SP2. As such, the areas of the first to third sub-pixels SP1 to SP3 may be modified according to embodiments.

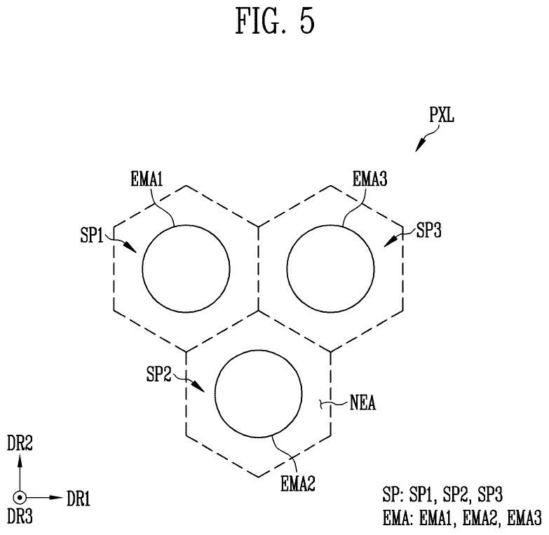

FIG. 5 is a schematic plan view illustrating the pixels PX according to an embodiment.

Referring to FIG. 5, the first to third sub-pixels SP1 to SP3 may have polygonal shapes in the third direction DR3 in a plan view. For example, the shapes of the first to third sub-pixels SP1 to SP3 may be hexagons as shown in FIG. 2.

The first to third emission areas EMA1 to EMA3 may have circular shapes when viewed in the third direction DR3. However, embodiments are not limited thereto. For example, each of the first to third emission areas EMA1 to EMA3 may have a polygonal shape.

The first and third sub-pixels SP1, SP3 may be arranged in the first direction DR1. The second sub-pixel SP2 may be disposed between the first sub-pixel SP1 and the third sub-pixel SP3 and shifted in the second direction DR2 such that the first, second, and third emission areas EMA1, EMA2, and EMA3 form vertices of a triangle.

The arrangements of sub-pixels shown in FIGS. 3 to 5 are illustrative, and embodiments are not limited thereto. Each pixel PXL may include two or more sub-pixels SP, which may be arranged in various ways, each of which may have various shapes, and each of emission areas EMA thereof may also have various shapes.

The display device 100 including a cover layer CV and a lower structure LST according to an embodiment will be described with reference to FIGS. 6 to 11. For convenience of description, any content that may overlap with the foregoing shall not be briefly explained or repeated.

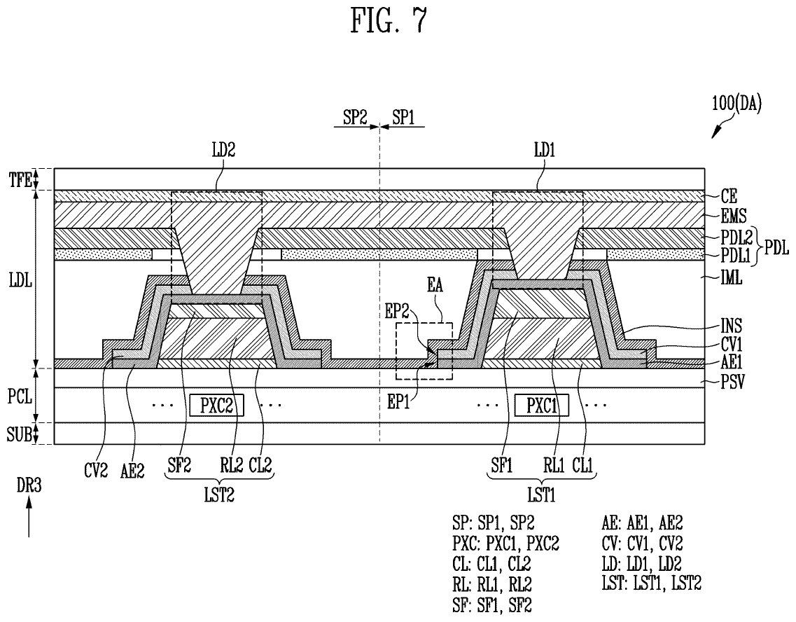

FIGS. 6 and 7 are schematic cross-sectional views illustrating the display device 100 according to an embodiment. FIGS. 6 and 7 illustrate a portion of the cross-sectional structures of the display device 100 in the display area DA, where FIG. 6 schematically illustrates the first to third sub-pixels SP1 to SP3, and FIG. 7 illustrates the sub-pixels SP that are adjacent to each other.

For convenience of description, FIG. 7 may schematically illustrate the first and second sub-pixels SP1 and SP2 as adjacent sub-pixels SP. The content described with reference to FIG. 7 and the like may be applied similarly to the structural feature between the first and third sub-pixels SP1 and SP3, and also to the structural feature between the second and third sub-pixels SP2 and SP3.

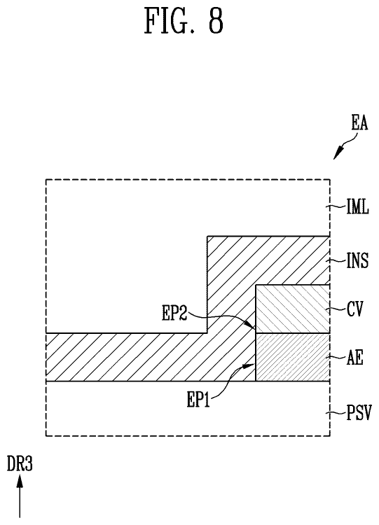

FIG. 8 is a view illustrating an area where the anode electrode AE and the cover layer CV are adjacent to each other according to an embodiment. FIG. 8 is a schematic enlarged view of the EA area of FIG. 7.

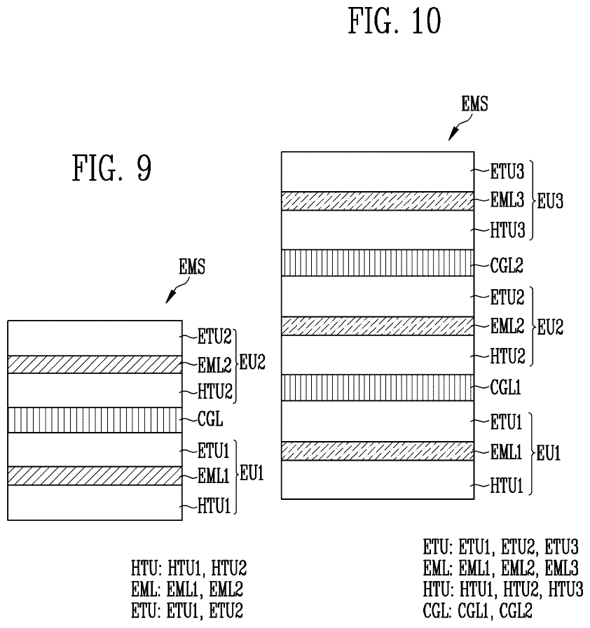

FIG. 9 is a schematic cross-sectional view of the light-emitting structure EMS according to an embodiment. FIG. 10 is a schematic cross-sectional view of the light-emitting structure EMS according to an embodiment.

Referring to FIGS. 6 to 10, the display device 100 may include the substrate SUB and layers on the substrate SUB in the display area DA.

The substrate SUB may include a silicon wafer substrate formed using a semiconductor process. The substrate SUB may include a semiconductor material suitable for forming the circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In some embodiments, the substrate SUB may include a glass substrate. In some embodiments, the substrate SUB may include a polyimide (PI) substrate.

The display device 100 may include the pixel circuit layer PCL.

The pixel circuit layer PCL may be disposed on the substrate SUB. The pixel circuit layer PCL may include the pixel circuits PXC disposed in the display area DA and configured to drive the light-emitting element LD. The pixel circuit layer PCL may include conductive layers and insulating layers, and the conductive layers may form the pixel circuit PXC. The pixel circuit PXC may include a first pixel circuit PXC1 configured to drive the first sub-pixel SP1 (for example, a first light-emitting element LD1), a second pixel circuit PXC2 configured to drive the second sub-pixel SP2 (for example, a second light-emitting element LD2), and a third pixel circuit PXC3 configured to drive the third sub-pixel SP3.

The pixel circuit layer PCL may further include a protective layer PSV covering the pixel circuits PXC. The protective layer PSV may be disposed below the light-emitting element layer LDL. The protective layer PSV may be an uppermost layer of the pixel circuit layer PCL. For example, the protective layer PSV may be a via layer. For example, a contact member (not shown) that electrically connects the pixel circuit PXC and the lower structure LST may be formed in the protective layer PSV. The protective layer PSV may include an inorganic material or an organic material.

The display device 100 may include the light-emitting element layer LDL.

The light-emitting element layer LDL may be disposed on the pixel circuit layer PCL. The light-emitting element layer LDL may include the lower structure LST, the anode electrode AE, the cover layer CV, an insulating layer INS, an intermediate layer IML, the pixel defining layer PDL, the light-emitting structure EMS, and the cathode electrode CE.

The lower structure LST may be disposed on the pixel circuit layer PCL (for example, the substrate SUB). The lower structure LST may be disposed on the protective layer PSV. The lower structure LST may be disposed below the light-emitting element LD. For example, the lower structure LST may be disposed below the anode electrode AE. The lower structure LST may be covered by the anode electrode AE. The lower structure LST may be disposed between the anode electrode AE and the substrate SUB.

The lower structure LST may be disposed on the substrate SUB so as to overlap the light-emitting element LD in a plan view. The lower structure LST may overlap the emission area EMA of each of the sub-pixels SP.

The lower structure LST has a thickness in the direction that is orthogonal to a surface of the substrate SUB (for example, the third direction DR3).

The lower structure LST may include a plurality of lower structures LST spaced apart from each another. For example, the lower structure LST may include a first lower structure LST1 included in the first sub-pixel SP1 and disposed below the first light-emitting element LD1, a second lower structure LST2 included in the second sub-pixel SP2 and disposed below the second light-emitting element LD2, and a third lower structure LST3 included in the third sub-pixel SP3 and disposed below the third light-emitting element LD3.

The lower structure LST may include a plurality of layers. In an embodiment, the lower structure LST may have a cross-section of a forward taper shape. According to an embodiment, the lower structure LST may have a cross-section of trapezoidal shape. For example, the conductive layer CL may have a width greater than that of a reflective layer RL and a step-forming layer SF, and the reflective layer RL may have a width greater than that of the step-forming layer SF.

The lower structure LST may include the conductive layer CL. The conductive layer CL may be disposed on the pixel circuit layer PCL. The conductive layer CL may be disposed (for example, directly disposed) on the protective layer PSV. The conductive layer CL may form a lower portion of the lower structure LST.

The conductive layer CL may include a plurality of conductive layers CL spaced apart from each other. For example, the conductive layer CL may include a first conductive layer CL1 included in the first sub-pixel SP1 and the first lower structure LST1, a second conductive layer CL2 included in the second sub-pixel SP2 and the second lower structure LST2, and a third conductive layer CL3 included in the third sub-pixel SP3 and the third lower structure LST3.

The conductive layer CL may be electrically connected to the pixel circuit PXC. For example, the conductive layer CL may be electrically connected to the pixel circuit PXC through a contact member penetrating the protective layer PSV. The conductive layer CL may be a bridge layer configured to supply an anode signal (for example, voltage) to the anode electrode AE.

The conductive layer CL may include a conductive material. For example, the conductive layer CL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. For example, the conductive layer CL may include a layer in which a titanium layer and a titanium nitride layer are sequentially disposed. However, the present disclosure is not limited thereto.

The lower structure LST may include the reflective layer RL. The reflective layer RL may be disposed on (for example, directly disposed on) the conductive layer CL. The reflective layer RL may form a middle portion of the lower structure LST.

The reflective layer RL may include a plurality of reflective layers RL spaced apart from each another. For example, the reflective layer RL may include a first reflective layer RL1 included in the first sub-pixel SP1 as part of the first lower structure LST1, a second reflective layer RL2 included in the second sub-pixel SP2 as part of the second lower structure LST2, and a third reflective layer RL3 included in the third sub-pixel SP3 as part of the third lower structure LST3.

The reflective layer RL may be electrically connected to the conductive layer CL.

The reflective layer RL may reflect light in a display direction (for example, the third direction DR3) of the display device 100. For example, the reflective layer RL may include a reflective surface facing the third direction DR3. The reflective layer RL may recycle light applied from the light-emitting element LD and output the light toward the outside. As the reflective layer RL is provided under the light-emitting element LD, the light emission efficiency of the display device 100 may be improved.

The reflective layer RL may function as a full mirror which reflects light emitted from the light-emitting structure EMS towards the display surface (or the cover window CW). The light emitted from the light-emitting layer EML of the light-emitting structure EMS may be amplified at least partially by reciprocating between the corresponding reflective layer RL and the cathode electrode CE, and the amplified light may be output through the cathode electrode CE.

The reflective layer RL may have a thickness greater than that of the conductive layer CL and the step-forming layer SF.

The reflective layer RL may include a conductive material. For example, the reflective layer RL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. For example, the reflective layer RL may include an aluminum layer having a relatively good reflectivity. However, the present disclosure is not limited thereto.

The lower structure LST may include the step-forming layer SF. The step-forming layer SF may be disposed on (for example, directly disposed on) the reflective layer RL. The step-forming layer SF may form an upper portion of the lower structure LST.

The step-forming layer SF may include a plurality of step-forming layers SF spaced apart from each other. For example, the step-forming layer SF may include a first step-forming layer SF1 included in the first sub-pixel SP1 and the first lower structure LST1, a second step-forming layer SF2 included in the second sub-pixel SP2 and the second lower structure LST2, and a third step-forming layer SF3 included in the third sub-pixel SP3 and the third lower structure LST3.

The light-emitting structure EMS is on the pixel defining layer PDL, as shown in FIG. 2. As shown in FIG. 6 and FIG. 7, where the pixel defining layer PDL is removed to form openings in the pixel defining layer PDL, the EMS is thicker to fill the openings. These thick portions of the EMS may herein be referred to as “resonance structures.” In some embodiments, the resonance structures of the light-emitting structure EMS may extend to a surface of the anode electrode AE.

The step-forming layers SF of the lower structure LST may have a greater thickness than the conductive layer CL. The thickness of the step-forming layer SF may determine a distance between the thick portions of the light-emitting structure EMS and the substrate SUB. For example, as illustrated in FIG. 7, the thicker the step-forming layer SF is, the farther is the distance between the light-emitting structure EMS on that step-forming layer SF and the reflective layer RL. Accordingly, the thickness of the step-forming layer SF is adjusted to achieve a desired resonance distance for each of the sub-pixels SP.

The thickness of the step-forming layers SF determine how far the resonance structure defined in each of the sub-pixels SP extends. The first step-forming layer SF1 may have a first thickness for achieving a resonance distance for the wavelength of light provided in the first sub-pixel SP1. The second step-forming layer SF2 may have a second thickness for forming a resonance distance for the wavelength of light provided in the second sub-pixel SP2. The third step-forming layer SF3 may have a third thickness for forming a resonance distance for the wavelength of light provided in the third sub-pixel SP3. At least some of the step-forming layers SF may have different thicknesses. For example, the first step-forming layer SF1 may have a greater thickness than the second step-forming layer SF2 and the third step-forming layer SF3. However, the present disclosure is not limited thereto. For example, in one of the sub-pixels SP, the step-forming layer SF may be omitted to achieve a resonance distance for the applicable wavelength.

The resonance distance adjusted for each of the sub-pixels SP may allow light in a specific wavelength range to be effectively and efficiently amplified, and may help achieve uniform light efficiency across the sub-pixels SP.

The step-forming layer SF may include an insulating material. For example, the step-forming layer SF may include an oxide material. The step-forming layer SF may include silicon oxide (SixOy). However, the present disclosure is not necessarily limited thereto.

The anode electrode AE may be disposed on the pixel circuit layer PCL. The anode electrode AE may cover the protective layer PSV. The anode electrode AE may cover the lower structure LST. At least a portion of the anode electrode AE may be disposed on the lower structure LST. For example, the anode electrode AE may cover (for example, entirely cover) side surfaces of each of the conductive layer CL, the reflective layer RL, and the step-forming layer SF. The anode electrode AE may cover (for example, entirely cover) an upper surface of the step-forming layer SF.

The anode electrode AE may be absent from at least a portion of the area between adjacent sub-pixels SP, such that a region between adjacent sub-pixels SP is free of anode electrode AE. In this anode-free region, a portion of the protective layer PSV may be not covered by the anode electrode.

The anode electrode AE may include a plurality of anode electrodes AE spaced apart from each other. For example, the anode electrode AE may include a first anode electrode AE1 included in the first sub-pixel SP1 and forming the first light-emitting element LD1, a second anode electrode AE2 included in the second sub-pixel SP2 and forming the second light-emitting element LDL2, and a third anode electrode AE3 included in the third sub-pixel SP3 and forming the third light-emitting element LD3.

At least the portion of the anode electrode AE may be disposed on an upper surface of the lower structure LST. Accordingly, the anode electrode AE may form an upper surface electrically connected to the light-emitting structure EMS at a top position of the lower structure LST. Each of the first, second, and third anode electrodes AE1, AE2, AE3 may be disposed on the first, second, and third step-forming layers SF1, SF2,and SF3, so that the first, second, and third anode electrodes AE1, AE2, AE3 may be formed at different heights.

The anode electrode AE may be electrically connected to the pixel circuit PXC through the conductive layer CL. Accordingly, the anode electrode AE may be provided with an anode voltage for the light-emitting structure EMS to emit light.

The anode electrode AE may include a first end EP1. The first end EP1 may include a side surface that forms an angle with respect to a surface of the substrate SUB. The first ends EP1 of adjacent sub-pixels SP may face each other.

The anode electrode AE may include a transparent conductive material. For example, the anode electrode AE may include at least one of transparent conductive materials such as indium tin oxide (ITO), indium zinc oxide (IZO), zinc oxide (ZnOx), indium gallium zinc oxide (IGZO), and indium tin zinc oxide (ITZO). However, the present disclosure is not limited thereto. According to an embodiment, the anode electrode AE may include titanium nitride (TiN).

The cover layer CV may be disposed on the anode electrode AE. According to an embodiment, the cover layer CV is disposed on a first portion of the anode electrode, the first portion including the side surface and the lower portion that is closest to the substrate SUB. The cover layer CV may not be disposed on a second portion of the anode electrode AE, the second portion including a center area of the top surface that is farthest from the substrate SUB. Furthermore, the cover layer CV is not disposed in the region between lower structures where the anode electrode AE is not disposed. For example, the cover layer CV may cover substantially all of the anode electrode AE except the second portion.

The cover layer CV may be directly on and contacting the upper surface of the anode electrode AE. For example, the cover layer CV may cover the anode electrode AE and have a second end EP2 on top of the first end EP1 of the anode electrode. The side surface of the first end EP1 and the side surface of the second end EP2 may be in parallel planes. In some embodiments, the side surfaces of the first end EP1 and the second end EP2 may be coplanar (flush with each other). As used herein, “coplanar” is included in “parallel planes.”

The cover layer CV may cover side surfaces of the lower structure LST. The cover layer CV may partially cover the upper surface of the lower structure LST. For example, the cover layer CV may not cover at least the portion (e.g., the second portion) of the anode electrode AE disposed on the lower structure LST. Accordingly, at least the second portion of the anode electrode AE on the lower structure LST may be exposed by the cover layer CV.

The cover layer CV may include a plurality of cover layers CV spaced apart from each another. For example, the cover layer CV may include a first cover layer CV1 included in the first sub-pixel SP1 and disposed on the first anode electrode AE1 (or the first lower structure LST1), a second cover layer CV2 included in the second sub-pixel SP2 and disposed on the second anode electrode AE2 (or the second lower structure LST2), and a third cover layer CV3 included in the third sub-pixel SP3 and disposed on the third anode electrode AE3 (or the third lower structure LST3).

The cover layer CV may include the second end EP2. The second end EP2 may include a side surface. For example, the second end EP2 may form an angle with respect to a top surface of the substrate SUB. The second end EP2 may face in the direction in which adjacent sub-pixels SP are adjacent to each other. The second end EP2 may be a side end of the cover layer CV.

The second end EP2 may face in the same direction as the first end EP1. The second end EP2 may be formed between adjacent lower structures LST, such that the second ends EP2 of the adjacent cover layers CV face each other.

The cover layer CV may be an etching mask for patterning the anode electrodes AE. For example, the anode electrodes AE may be formed by using the cover layer CV as an etching mask. Accordingly, the anode electrodes AE may be arranged in a region corresponding to the cover layer CV.

The cover layer CV may overlap the anode electrode AE in a plan view. For example, the cover layer CV may cover the first end EP1 of the anode electrode AE in a plan view. According to an embodiment, the cover layer CV may cover the first end EP1 of the anode electrode AE as a whole, in a plan view.

According to an embodiment, the second end EP2 of the cover layer CV may overlap, in a plan view, the first end EP1 of the anode electrode AE. For example, the first end EP1 and the second end EP2 may be formed on a same plane. However, the present disclosure is not limited thereto. For example, the cover layer CV may extend beyond the anode electrode AE, and thus the first end EP1 may overlap a portion of an inner surface of the cover layer CV in a plan view.

The cover layer CV may include an inorganic material. For example, the cover layer CV may include an inorganic oxide. According to an embodiment, the cover layer CV may include a tetraethyl orthosilicate (TEOS). The cover layer CV may include silicon oxide (SixOy). According to an embodiment, the cover layer CV may have a composition that is not mixed with a material other than an inorganic oxide. However, the present disclosure is not limited thereto.

According to an embodiment, the cover layer CV includes an inorganic material and may be formed through a deposition process. Accordingly, the cover layer CV may have a relatively thin thickness. Accordingly, when a dry etching process for forming the anode electrode AE is performed using the cover layer CV as an etching mask (for example, a hard mask), unintended residues may be formed at a relatively low height (or thin thickness) around the cover layer CV. For example, the cover layer CV may have a thickness of 1000 Angstroms or less. For example, the cover layer CV may have a thickness in a range of 500 to 1000 Angstroms. For example, the cover layer CV may have a thickness in a range of 700 to 900 Angstroms. However, the present disclosure is not necessarily limited thereto.

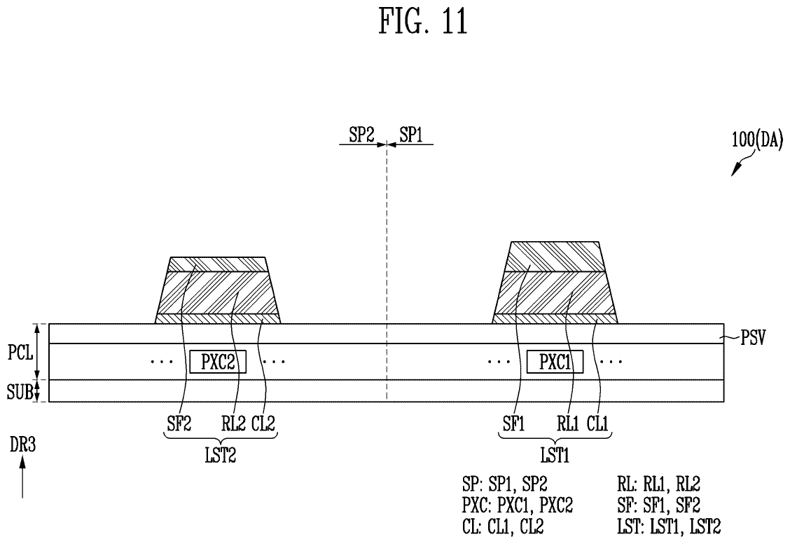

The time required for the cleaning process is reduced in such case, and the convenience of the cleaning process may be improved. Detailed descriptions thereof will be described below with reference to the drawings after FIG. 11.

The insulating layer INS may be disposed across the sub-pixels SP. The insulating layer INS may be disposed on the protective layer PSV between the anodes AE, and may cover the lower structure LST, the anode electrode AE, and the cover layer CV.

At least a portion of the insulating layer INS may be disposed in the region between adjacent lower structures LST where the anode electrode AE is not disposed. For example, the insulating layer INS may cover the region in which the anode electrodes AE are not disposed in a region between adjacent sub-pixels SP. According to an embodiment, the insulating layer INS may cover the first end EP1 of the anode electrode AE1 and may cover the second end EP2 of the cover layer CV.

The insulating layer INS may expose the portion of the anode electrode AE on the lower structure LST. For example, the insulating layer INS may equally expose the portion of the anode electrode AE exposed by the cover layer CV.

The insulating layer INS may be a chemical mechanical polishing (CMP) stopper layer for the intermediate layer IML formed through a CMP process. For example, an upper surface of at least the portion of the insulating layer INS disposed across the sub-pixels SP may not be covered by the intermediate layer IML.

The insulating layer INS may include an inorganic material. For example, the insulating layer INS may include silicon nitride (SixNy). However, the present disclosure is not limited thereto.

The intermediate layer IML may fill a region between the lower structures LST of the sub-pixels SP. The intermediate layer IML may offset the step formed by the lower structures LST, or the like. The intermediate layer IML may be disposed between adjacent lower structures LST, and may be disposed on at least a portion of the lower structures LST.

The intermediate layer IML may be a planarization layer. The intermediate layer IML may be formed to fill the region between the lower structures LST and then planarized through a CMP process. The planarization may be done to make the upper surface of the intermediate layer IML flush with the uppermost surface of the insulating layer INS. According to an embodiment, the intermediate layer IML may include an oxide material. For example, the intermediate layer IML may include silicon oxide (SixOy) or the like. However, the present disclosure is not limited thereto.

The intermediate layer IML may expose the portion of the anode electrode AE on the lower structure LST. For example, the intermediate layer IML may equally expose the portion of the anode electrode AE to which the cover layer CV and the insulating layer INS are exposed.

The pixel defining layer PDL may be disposed on the intermediate layer IML. At least a portion of the pixel defining layer PDL may be disposed in the region between adjacent sub-pixels SP.

The pixel defining layer PDL may define a region in which the portion of the light-emitting structure EMS is disposed.

The pixel defining layer PDL may form a T-shaped structure. The pixel defining layer PDL may form a protruding tip structure. For example, the pixel defining layer PDL may include a first pixel defining layer PDL1 having a relatively narrow width (for example, a first width) and a second pixel defining layer PDL2 disposed on the first pixel defining layer PDL1 and having a relatively wide width (for example, a second width larger than the first width). The “width,” as used herein, is a distance in the first direction DR1 or the second direction DR2.

The pixel defining layer PDL may define a boundary region between the sub-pixels SP. For example, the pixel defining layer PDL may cause a discontinuity to be formed in the light-emitting structure EMS in the boundary region. For example, at least the portion of the light-emitting structure EMS may be broken or bent in the boundary region by the pixel defining layer PDL. For example, at least some of the layers formed in each of the first to third sub-pixels SP1 to SP3 among the plurality of layers included in the light-emitting structure EMS may have discontinuous sections. For example, a portion of a charge generation layer CGL (refer to FIG. 9) or a portion of the hole transport unit HTU included in the light-emitting structure EMS may be broken by the pixel defining layer PDL. Accordingly, the risk of leakage current may be reduced, and the sub-pixels SP may have operating characteristics with improved reliability.

The pixel defining layer PDL may include various materials. For example, the pixel defining layer PDL may include one or more of silicon oxide (SixOy) and silicon nitride (SixNy). According to an embodiment, the first pixel defining layer PDL1 may include a first inorganic material, and the second pixel defining layer PDL2 may include a second inorganic material different from the first inorganic material. However, the present disclosure is not limited thereto.

The light-emitting structure EMS may be disposed across the sub-pixels SP, and at least the portion of the light-emitting structure EMS may be disposed on one surface of the anode electrode AE to which the cover layer CV, the insulating layer INS, the intermediate layer IML, and the pixel defining layer PDL are exposed.

The light-emitting structure EMS may include a multilayer structure electrically connected between the anode electrode AE and the cathode electrode CE.

According to an embodiment (refer to FIG. 9), the light-emitting structure EMS may have a tandem structure in which a first light-emitting unit EU1 and a second light-emitting unit EU2 are stacked. The light-emitting structure EMS may be configured substantially identically in each of the first to third light-emitting elements LD1 to LD3.

The light-emitting structure EMS may each include the hole transport unit HTU, the light-emitting layer EML, and the electron transport unit ETU, and may further include the charge generation layer CGL. Each of the layers forming the light-emitting structure EMS may include an organic material, and may further include, according to an embodiment, a metal-containing compound or an inorganic material such as quantum dots or the like.

The hole transport unit HTU may include a multilayer structure having a plurality of layers each containing a different material. For example, the hole transport unit HTU may include a hole injection layer and a hole transport layer, and may further include a light-emitting auxiliary layer, an electron blocking layer, and the like, according to an embodiment.

The light-emitting layer EML may include a material capable of emitting light of a color. The light-emitting layer EML may include a host and a dopant. The host of the light-emitting layer is a light-emitting material that may capture carriers (electrons and holes) for light to be generated, and may induce efficient generation of excitons. The dopant may include a phosphorescent dopant or a fluorescent dopant. According to an embodiment, the example of the dopant is not particularly limited. According to an embodiment, the dopant may include one organic material and may also include a metal complex, or the like.

The electron transport unit ETU may include a multilayer structure having a plurality of layers each comprising different materials. The electron transport unit ETU may include an electron injection layer and an electron transport layer ETL, and may further include an electron buffer layer, a hole blocking layer, and the like, according to an embodiment.

The first light-emitting unit EU1 may include a first light-emitting layer EML1, a first electron transport unit ETU1, and a first hole transport unit HTU1. The first emitting layer EML1 may be disposed between the first electron transport unit ETU1 and the first hole transport unit HTU1. The second light-emitting unit EU2 may include a second light-emitting layer EML2, a second electron transport unit ETU2, and a second hole transport unit HTU2. The second emitting layer EML2 may be disposed between the second electron transport unit ETU2 and the second hole transport unit HTU2.

A connecting layer, which may be provided in a form of the charge generation layer CGL, may be disposed between the first and second light-emitting units EU1 and EU2 to electrically connect the first and second light-emitting units EU1 and EU2 to each other. In some embodiments, the charge generation layer CGL may have a stacked structure of a p-dopant layer and an n-dopant layer. For example, the p-dopant layer may include p-type dopants such as HAT-CN, TCNQ, NDP-9, or the like, and the n-dopant layer may include alkali metals, alkaline earth metals, lanthanide-based metals, or combinations thereof. However, some embodiments are not limited thereto.

In some embodiments, the first emitting layer EML1 and the second emitting layer EML2 may generate light of different colors from each other. The light emitted from each of the first light-emitting layer EML1 and the second light-emitting layer EML2 may be mixed and visually recognized as white light. For example, the first light-emitting layer EML1 may generate blue color light, and the second light-emitting layer EML2 may generate yellow color light. In some embodiments, the second light-emitting layer EML2 may include a structure in which a first sub-light-emitting layer generating red color light and a second sub-light-emitting layer generating green color light are stacked. The red color light and the green color light may be mixed to provide yellow color light. In this case, an intermediate layer performing a function of transporting holes and/or a function of blocking the transport of electrons may be further disposed between the first and second sub-light-emitting layers.

According to an embodiment (refer to FIG. 10), the light-emitting structure EMS may have a tandem structure in which first to third light-emitting units EU1 to EU3 are stacked. The light-emitting structure EMS may be configured substantially identically in each of the first to third light-emitting elements LD1 to LD3 of FIG. 6.

The first light-emitting unit EU1 may include the first light-emitting layer EML1, the first electron transport unit ETU1, and the first hole transport unit HTU1. The first emitting layer EML1 may be disposed between the first electron transport unit ETU1 and the first hole transport unit HTU1. The second light-emitting unit EU2 may include the second light-emitting layer EML2, the second electron transport unit ETU2, and the second hole transport unit HTU2. The second emitting layer EML2 may be disposed between the second electron transport unit ETU2 and the second hole transport unit HTU2. The third light-emitting unit EU3 may include a third light-emitting layer EML3, a third electron transport unit ETU3, and a third hole transport unit HTU3. The third emitting layer EML3 may be disposed between the third electron transport unit ETU3 and the third hole transport unit HTU3.

A first charge generation layer CGL1 may be disposed between the first and second light-emitting units EU1 and EU2. A second charge generation layer CGL2 may be disposed between the second and third light-emitting units EU2 and EU3.

In some embodiments, the first to third light-emitting layers EML1 to EML3 may generate light of different colors from each other. The light emitted from each of the first to third light-emitting layers EML1 to EML3 may be mixed and visually recognized as white light. For example, the first emitting layer EML1 may generate blue color light, the second emitting layer EML2 may generate green color light, and the third emitting layer EML3 may generate red color light.

The cathode electrode CE may be disposed on the light-emitting structure EMS in the display area DA. The cathode electrode CE may be provided in common to the first to third sub-pixels SP1 to SP3. The cathode electrode CE may function as a half mirror that partially transmits and partially reflects light emitted from the light-emitting structure EMS. However, the present disclosure is not limited thereto.

The light-emitting element LD may include the first light-emitting element LD1 of the first sub-pixel SP1 that includes the first anode electrode AE1, a first light-emitting unit of the light-emitting structure EMS, and a first cathode portion of the cathode electrode CE, a second light-emitting element LD2 of the second sub-pixel SP2 that includes the second anode electrode AE2, a second light-emitting unit of the light-emitting structure ELS, and a second cathode portion of the cathode electrode CE, and a third light-emitting element LD3 of the third sub-pixel SP3 that includes the third anode electrode AE3, a third light-emitting unit of the light-emitting structure EMS and a third cathode portion of the cathodic electrode CE.

The encapsulation layer TFE (see FIG. 2) may be disposed on the cathode electrode CE. The encapsulation layer TFE may encapsulate the first to third light-emitting elements LD1 to LD3. According to an embodiment, the encapsulation layer TFE may be a thin film encapsulation, but the present disclosure is not limited thereto.

A method of manufacturing the display device 100 according to an embodiment will be described with reference to FIGS. 11 to 20. For convenience of description, any content that may overlap with the foregoing shall not be briefly explained or repeated.

FIGS. 11 to 20 are schematic cross-sectional views at each process stage illustrating the method of manufacturing the display device 100 according to an embodiment. For convenience of description, FIGS. 11 to 20 are shown based on the cross-sectional structure described above with reference to FIG. 7.

Referring to FIG. 11, the substrate SUB may be provided, the pixel circuits PXC may be patterned on the substrate SUB to form the pixel circuit layer PCL, and the protective layer PSV covering the pixel circuits PXC may be formed.

According to an embodiment, the conductive layer or the insulating layer on the substrate SUB may be formed using a conventional process of manufacturing a semiconductor device. For example, the conductive layer or the insulating layer on a base layer BSL may be formed by a photolithography process, may be etched by various methods (wet etching, dry etching, or the like), and may be deposited by various methods (sputtering, chemical vapor deposition, or the like). In addition, a photoresist material used to form the etching mask may be of a negative type or a positive type. The present disclosure is not necessarily limited to specific examples.

The lower structure LST may be formed on the protective layer PSV in each of the sub-pixels SP. For example, the first sub-structure LST1 may be patterned in the first sub-pixel SP1, and the second sub-structure LST2 may be patterned on the second sub-pixel SP2.

The first and second conductive layers CL1 and CL2 may be patterned in the same process. The first and second reflective layers RL1 and RL2 may be patterned in the same process. The first and second step-forming layers SF1 and SF2 may be patterned in the same process. According to an embodiment, a mask including a half tone portion may be used to form the first and second step-forming layers SF1 and SF2, but the present disclosure is not limited thereto. According to an embodiment, the first step-forming layer SF1 may be patterned to be thicker than the second step-forming layer SF2.

In this step, the first and second lower structures LST1 and LST2 may be spaced apart from each other in the direction in which the first and the second sub-pixels SP1 and SP2 are spaced apart from each other. The first and second lower structures LST1 and LST2 may be patterned in respective positions where the emission areas EMA will be formed.

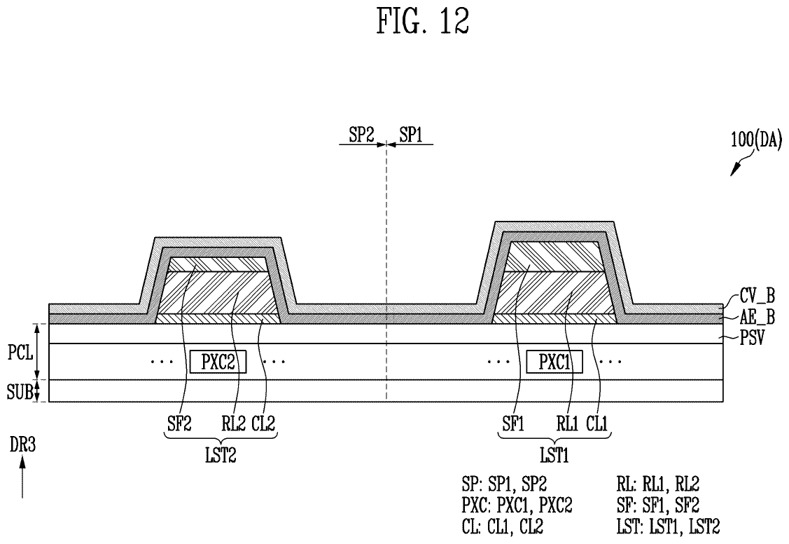

Referring to FIG. 12, a base anode electrode AE_B and a base cover layer CV_B may be formed (for example, disposed) to cover the lower structures LST.

During the process depicted in FIG. 12, the base anode electrode AE_B and the base cover layer CV_B may be deposited. According to an embodiment, the base cover layer CV_B may be formed by an atomic layer deposition (ALD) process. The base cover layer CV_B may be deposited using a suitable method to form a thin layer.

According to an embodiment, the base cover layer CV_B includes an oxide such as TEOS, and is formed by an ALD process, so that a lower step and the like may be effectively covered.

On the other hand, experimentally, when the anode electrode AE is formed to have an unintended protruding structure such as a hillock, there may be a risk that the protruding structure of the anode electrode AE may be exposed by other subsequent processes (for example, a CMP process, or the like).

In this case, a possibility of providing the materials used in the manufacturing process to the anode electrode AE and the lower structure LST through the protruding structure of the anode electrode AA or the like may exist. For example, when some of the materials used in the manufacturing process are provided to the reflective layer RL including aluminum (Al) or the like, there may be a risk that visibility may be impaired, such as when a portion of the reflective layer RL is damaged and haze or the like occurs.

In addition, experimentally, when a nitride or the like is deposited on the base anode electrode AE_B including Indium Tin Oxide (ITO), a high-concentration hydrogen environment may be created to deposit the nitride, thereby forming a protruding structure such as a hillock or the like on the base anode electrode AE_B including ITO.

However, according to an embodiment, since the base cover layer CV_B includes an oxide such as TEOS, an upper surface of the base anode electrode AE_B may have a flat shape that does not include a protruding structure (for example, a protrusion) such as a hillock. In this case, the upper surface of the anode electrode AE may have a flat shape that does not include a protruding structure such as a hillock.

As a result, according to an embodiment, since the base cover layer CV_B including an oxide other than nitride or the like is deposited on the base anode electrode AE_B, the above-described risk may be reduced, and as a result, the display device 100 having excellent display quality such as visibility and improved reliability may be provided.

In this step, the base anode electrode AE_B may be formed across the first and second sub-pixels SP1 and SP2, and may cover the first and second lower structures LST1 and LST2. The base anode electrode AE_B may be a conductive portion formed to pattern the anode electrode AE.

In this step, the base cover layer CV_B may be formed across the first and second sub-pixels SP1 and SP2, and may cover the base anode electrode AE_B and the first and second lower structures LST1 and LST2. The base cover layer CV_B may be an inorganic insulating portion formed to pattern the cover layer CV.

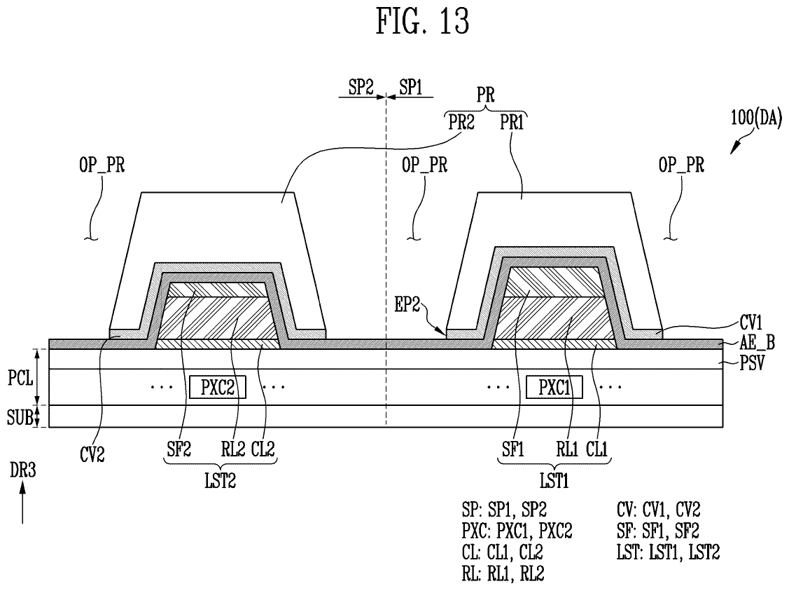

Referring to FIG. 13, the base cover layer CV_B may be patterned to form the cover layers CV.

During the process depicted in FIG. 13, the base cover layer CV_B may be etched and the first and second cover layers CV1 and CV2 spaced apart from each other may be formed (for example, patterned). For example, a photoresist layer PR including photoresist openings OP_PR may be patterned on the base cover layer CV_B. According to an embodiment, the base cover layer CV_B may be etched by using the photoresist layer PR as an etching mask, and a portion of the base cover layer CV_B corresponding to the photoresists opening OP_PR may be removed to provide the cover layers CV.

According to an embodiment, the base cover layer CV_B may be dry etched.

As the etching process proceeds, a portion of the patterned cover layer CV may be exposed to form the second end EP2.

At least a portion of the base anode electrode AE_B may be exposed. For example, the base anode electrode AE_B may be exposed at the photoresist opening OP_PR.

The etching process for the base anode electrode AE_B may not proceed. That is, according to an embodiment, the photoresist layer PR may not be used as an etching mask to pattern the anode electrode AE.

According to an embodiment, the photoresist layer PR may include a first photoresist layer PR1 formed in the first sub-pixel SP1 and a second photoresist layer PR2 formed in the second sub-pixel SP2. A portion of the base cover layer CV_B overlapping the first photoresist layer PR1 in a plan view may not be removed, and the first cover layer CV1 may be formed under the first photoresist layer PR1. A portion of the base cover layer CV_B overlapping the second photoresist layer PR2 in a plan view may not be removed, and the second cover layer CV2 may be formed under the second photoresist layer PR2.

According to an embodiment, the photoresist layer PR may cover the entirety of the lower structure LST. For example, the first photoresist layer PR1 may cover the entire first lower structure LST1, and the second photoresist layer PR2 may cover the entire second lower structure LST2.

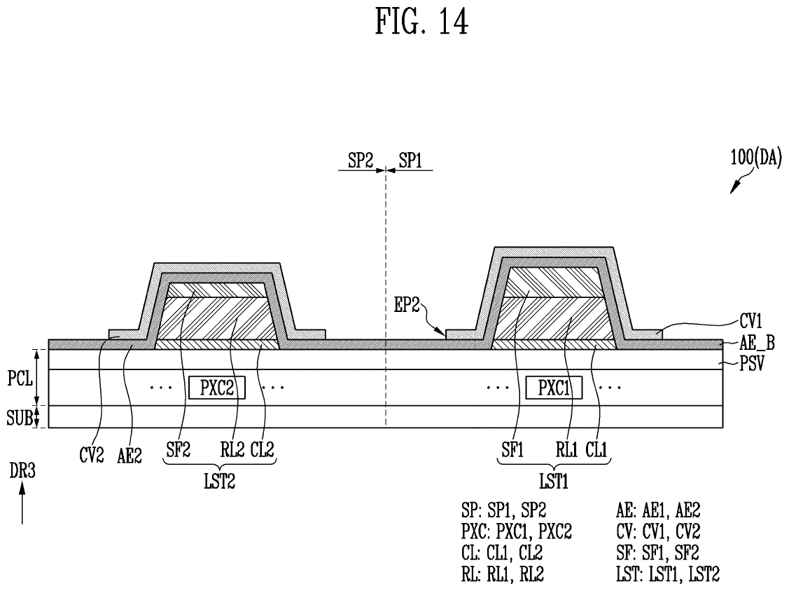

Referring to FIG. 14, the photoresist layer PR may be removed.

The photoresist layer PR may be removed to expose an upper surface of the cover layers CV. According to an embodiment, no other layer may be arranged on an upper portion of the cover layer CV. According to an embodiment, the photoresist layer PR may be removed based on an ashing process or the like.

In this step, the etching process for the base anode electrode AE_B may still not be performed.

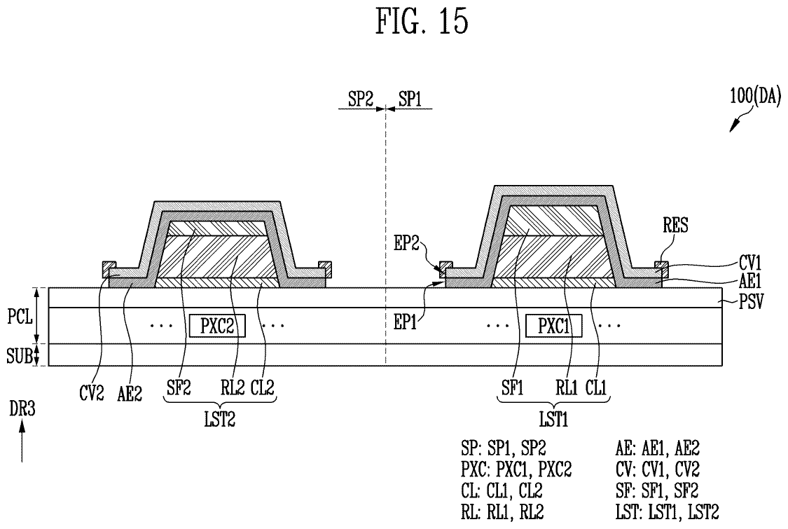

Referring to FIG. 15, the base anode electrode AE_B may be patterned and the anode electrodes AE may be provided.

In this step, the base anode electrode AE_B may be etched and the first and second anode electrodes AE1 and AE2 spaced apart from each other may be provided (for example, patterned). For example, the base anode electrode AE_B may be etched using the cover layer CV as an etching mask, and the portion of the base anode electrode AE_B exposed by the cover layer CV may be removed to provide the anode electrodes AE.

According to an embodiment, the base anode electrode AE_B may be dry etched.

As the etching process proceeds, a portion of the patterned anode electrode AE may be removed to form the first end EP1.

At this stage, at least the portion of the protective layer PSV that was under the removed portion of the anode electrode AE may become exposed.

The dry etching process for patterning the anode electrode AE may be performed with the upper surface of the cover layer CV exposed. That is, when the dry etching process according to the embodiment is performed, the cover layer CV may be used as an etching mask, but another layer may not be formed on the upper portion of the cover layer CV. Thus, the structure is coverable by the cover layer CV, and a structure that is too tall to be covered by the cover layer CV may not be formed at the upper portion of the base anode electrode AE_B. According to an embodiment, only a cover layer CV that is thin may be disposed on the upper portion of the base anode electrode AE_B as the base anode electrode AE_B is formed with an inorganic material.

During this process, since the cover layer CV may be used as a hard etch mask, the first end EP1 and the second end EP2 may be formed at positions corresponding to each other. For example, the first end EP1 and the second end EP2 may be formed to overlap (for example, the side surfaces are flush). Alternatively, according to an embodiment, the first end EP1 may be formed further inward than the second end EP2 when the anode electrode AE partially forms an under-cut structure at a lower portion of the cover layer CV. In this case, the cover layer CV may entirely cover the anode electrode AE in a plan view, and a portion of the cover layer CV may not overlap the anode electrode AE in a plan view.

According to an embodiment, the portion of the base anode electrode AE_B may not be removed from under the first cover layer CV1, and the first anode electrode AE1 may be formed under the first cover layer CV1. The portion of the base anode electrode AE_B may not be removed from under the second cover layer CV2, and the second anode electrode AE2 may be formed under the second cover layer CV2.

During this process, when the anode electrode AE is patterned, a residue portion RES may be formed as shown in FIG. 15.

The residue portion RES may be formed around the cover layer CV used as an etching mask when the dry etching process for patterning the anode electrode AE is performed. For example, the residue portion RES may include at least some of a same material as the material forming the anode electrode AE. For example, when the anode electrode AE includes Indium Tin Oxide (ITO), the residue portion RES may also include an indium-based material (for example, ITO).

The residue portion RES may be formed to cover the second end EP2 of the cover layer CV.

Experimentally, when etching conductive materials, residue portions may be formed around an etching mask for etching the conductive materials. For example, when the base anode electrode AE includes ITO, reactants such as indium (In) may be re-deposited around the cover layer CV in an etching environment.

In this case, the range (e.g., the range corresponding to the thickness of the cover layer CV) in which the residue portion RES is formed may be determined according to the height of the etching mask used. For example, as the height of the etching mask increases, more residue portions may be formed.

According to an embodiment, in the etching process for forming the anode electrode AE, a cover layer CV may be used as an etching mask. Since the cover layer CV is thin, the residue portion RES may be formed in a relatively limited space. For example, the residue portion RES may be formed to not differ dramatically from the thickness of the cover layer CV.

According to an embodiment, the substrate SUB may be fixed by various types of chucks (not shown) in order to perform an etching process on the substrate SUB. At this time, since the chuck is disposed adjacent to the substrate SUB, the temperature on the substrate SUB may be changed by adjusting the temperature of the chuck. The chuck may fix the substrate SUB when the etching process is performed, such as patterning the anode electrode AE.

According to an embodiment, the anode electrodes AE may be patterned using the cover layer CV including an inorganic oxide (for example, TEOS), so that the chuck connected to the substrate SUB may be set to have a relatively high temperature. For example, the chuck may be heated to about 80 degrees. In this case, since a relatively high temperature environment is formed on the substrate SUB, the space in which the residue portion RES is formed may be further reduced.

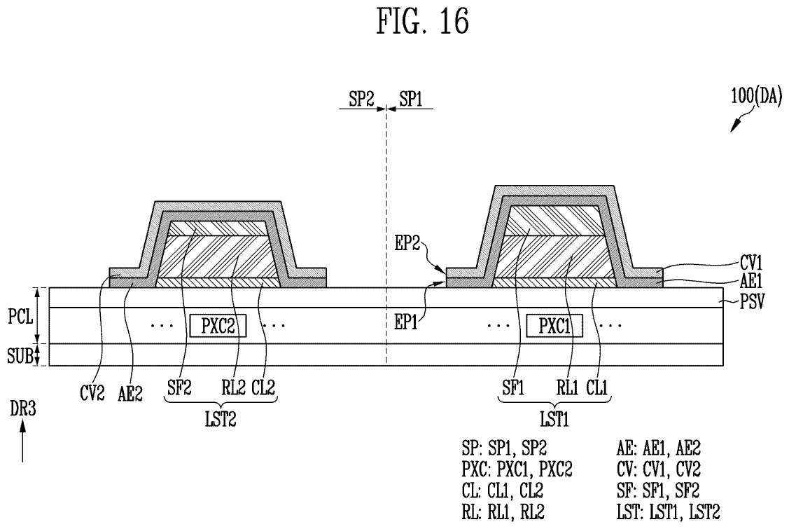

Referring to FIG. 16, the residue portion RES may be removed.

The residue portion RES may be removed to expose the second end EP2 of the cover layer CV. According to an embodiment, the residue portion RES may be removed by a wet cleaning method using a Diluted HF (DHF) process. However, the present disclosure is not limited thereto.

As described above, the residue portion RES may be formed in the relatively small space. Accordingly, the time required for the cleaning process to remove the residue portion RES may be reduced. Furthermore, when a wet cleaning method is used and excessive cleaning process time is required, there may be a risk of rust forming in the reflective layer RL or the like. For example, when the reflective layer RL includes aluminum (Al) and the cleaning process proceeds for a long time, there may be a risk that an oxide layer is formed on an outer surface of the reflective layer RL.

However, according to an embodiment, the physical space where the residue portion RES is formed is determined based on the cover layer CV, so that the residue portion RES may be controlled to be disposed in a narrow area, and thus the time required for the wet cleaning method may be reduced. Furthermore, since the risk of rust or the like being formed in the reflective layer RL is reduced, even when a conductive material having an excellent reflectance such as aluminum (Al) is applied to the reflective layer RL, the process risk is reduced, and the operation reliability of the display device 100 may be improved.

The residue portion RES removed by the wet cleaning method may generally be formed on the cover layer CV and not on the anode electrode AE. In this case, the residue portion RES may have a first etch ratio with respect to the cover layer CV and a second etch ratio smaller than the first etch ratio with respect to the anode electrode AE. That is, the residue portion RES is generally formed on the cover CV, so that the residue portion RES may be removed more efficiently.

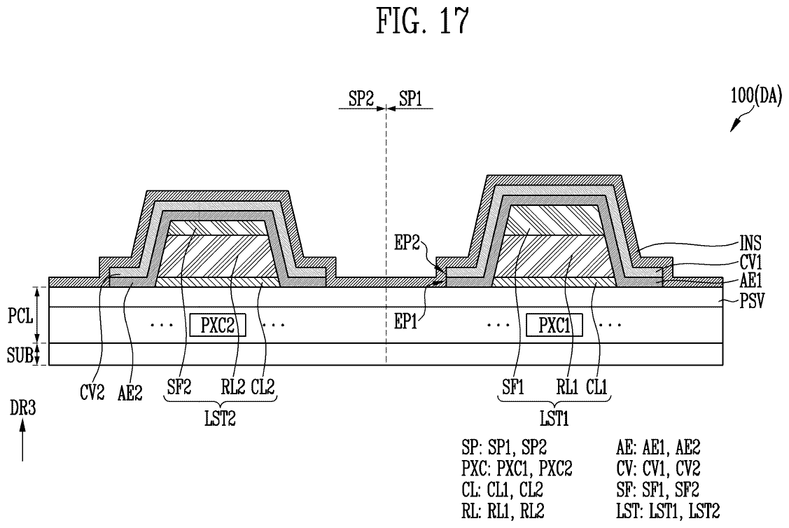

Referring to FIG. 17, the insulating layer INS may be disposed across the sub-pixels SP.

During the process depicted in FIG. 17, the insulating layer INS may be deposited, and the insulating layer INS may cover the lower structures LST, the anode electrodes AE, and the cover layers CV. Accordingly, the anode electrode AE may be entirely covered by the other layers. The insulating layer INS may be formed continuously across neighboring sub-pixels SP.

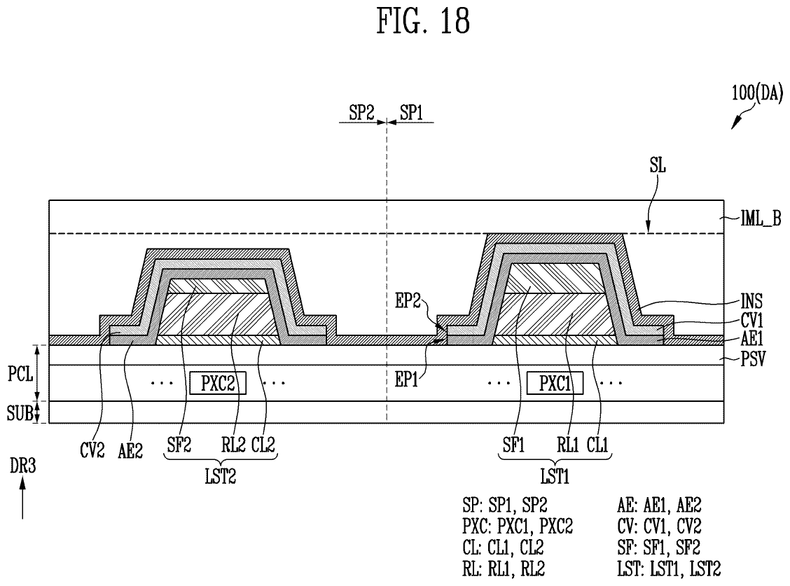

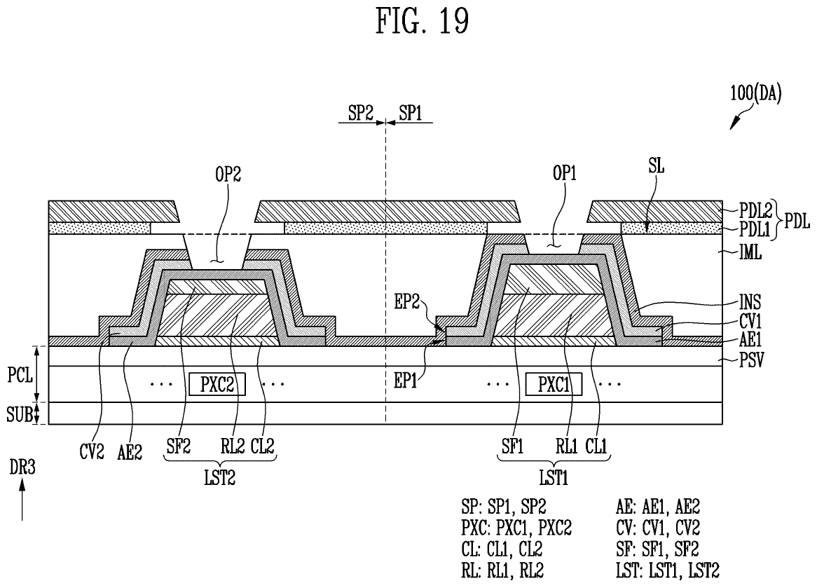

Referring to FIGS. 18 and 19, a base intermediate layer IML_B may be formed, and the base intermediate layer IML_B may be polished and formed into the intermediate layer IML.

The base interlayer IML_B may be a layer for forming the intermediate layer IML for planarizing the lower structures. After the base intermediate layer IML_B is formed to cover the highest portion of the insulating layer INS, the base intermediate layer IML_B may be polished by a CMP process. The base interlayer IML_B may be polished to a polishing stopper plane SL, so that the intermediate layer IML exposing a highest portion of the insulating layer INS may be formed. The polishing stopper plane SL may be a virtual plane flush with the upper surface of the highest portion of the insulating layer INS (“uppermost surface” of the insulating layer INS).

Referring to FIG. 19, after the intermediate layer IML is formed, first and second openings OP1 and OP2 may be formed by removing select parts of the insulating layer INS and the cover layers CV1, CV2. The first and second openings OP1, OP2 may expose the first anode electrode AE1 and the second anode electrode AE2 on the lower structures LST1, LST2. The first and second openings OP1, OP2 may be positioned above the respective center portions of the top surfaces of the lower structures LST1, LST2. In some embodiments, a pixel defining layer PDL is deposited on the intermediate layer IML, and the pixel defining layer PDL may be patterned.

In an embodiment, the first and second openings OP1 and OP2 may be formed after the pixel defining layer PDL is patterned. In another embodiment, the pixel defining layer PDL may be patterned after the first and second openings OP1 and OP2 are formed.

The pixel defining layer PDL may be patterned on the intermediate layer IML. The pixel defining layer PDL may be patterned in the same process as the etching process for forming the first and second openings OP1 and OP2, or may be patterned through one or more different processes.

The first pixel defining layer PDL1 and the second pixel defining layer PDL2 including different materials may be patterned, respectively. According to an embodiment, the first pixel defining layer PDL1 may be etched to form an under-cut structure with respect to the second pixel defining layer PDL2. Accordingly, the pixel defining layer PDL forming a tip structure may be provided.

An upper surface of the first anode electrode AE1 on the first lower structure LST1 in the first sub-pixel SP1 may be exposed by the first opening OP1. An upper surface of the second anode electrode AE2 on the second lower structure LST2 in the second sub-pixel SP2 may be exposed by the second opening OP2.

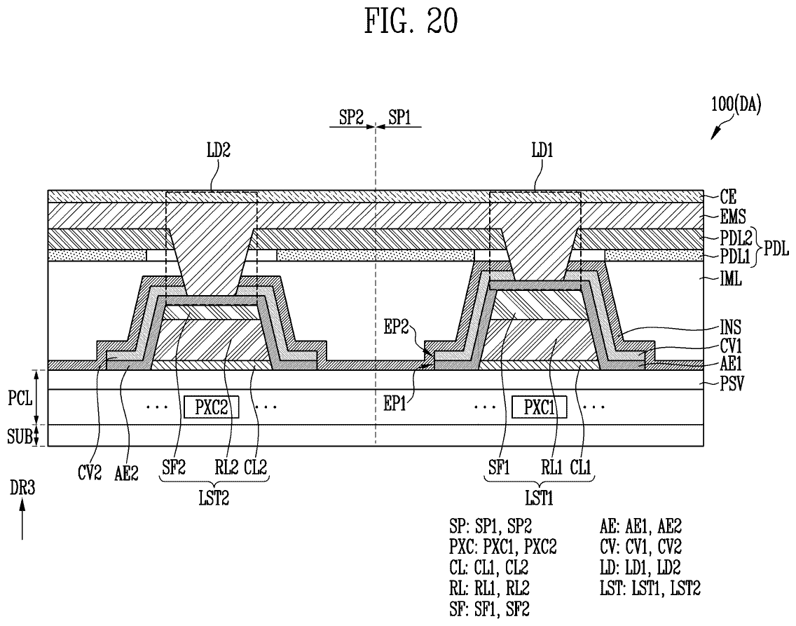

Referring to FIG. 20, the light-emitting structure EMS and the cathode electrode CE may be formed across the sub-pixels SP in the display area DA.

The light-emitting structure EMS may be formed by vacuum deposition, inkjet printing, or the like, but embodiments are not limited thereto.

A portion of the light-emitting structure EMS fills the first opening OP1 and the second opening OP2 that extend through the pixel defining layer PDL, the insulating layer INS, and the cover layer CV.

The deposition of the light emitting structure EMS and the cathode electrode CE forms light-emitting elements LD including the first and second light-emitting elements LD1 and LD2.

Then, according to the embodiment, other layers such as the encapsulation layer TFE may be further disposed on the cathode electrode CE, and the display device 100 according to the embodiment may be provided.

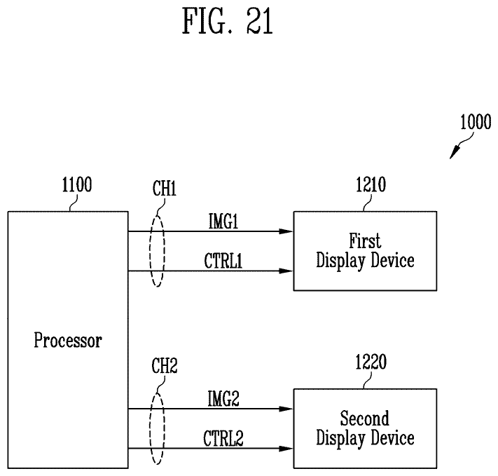

Examples in which the display device 100 according to an embodiment is applied will be described with reference to FIGS. 21 to 28.

FIG. 21 is a block diagram illustrating an embodiment of an electronic device 1000.

Referring to FIG. 21, the electronic device 1000 may include a processor 1100 and one or more display devices 1210 and 1220. The electronic device 1000 may implement a display system.

The processor 1100 may perform various tasks and calculations. In some embodiments, the processor 1100 may include an application processor, a graphics processor, a microprocessor, a central processing unit (CPU), or the like. The processor 1100 may be connected to other components of the electronic device 1000 through a bus system to control them.

According to an embodiment, the processor 1100 may provide input image data to the display devices 1210 and 1220, so that the display devices 1220 and 1220 may display an image based on the input image data provided from the processor 1100.

In FIG. 21, the electronic device 1000 is being illustrated as including the first and second display devices 1210 and 1220. The processor 1100 may be connected to the first display device 1210 through a first channel CH1, and may be connected to a second display device 1220 through a second channel CH2.

Through the first channel CH1, the processor 1100 may transmit first image data IMG1 a first control signal CTRL1 to the first display device 1210. The first display device 1210 may display an image based on the first image data IMG1 and the first control signal CTRL1. The first display device 1210 may be configured similarly to the display device 100 described above.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described above.

The electronic device 1000 may include a portable computer, a mobile phone, a smart phone, a tablet personal computer (PC), and a computing system that provides image display functions such as a smart watch, a watch phone, a portable multimedia player (PMP), navigation, an ultra mobile personal computer (UMPC), and the like. In addition, the electronic device 1000 may include at least one of a head mounted display (HMD), a virtual reality (VR) device, a mixed reality (MR) device, and an augmented reality (AR) device.

Meanwhile, according to an embodiment, the electronic device 1000 may further include a memory device, a storage device, an input/output device, and a power supply.

The memory device may store data necessary for the operation of the electronic device 1000. For example, the memory device may include a non-volatile memory device such as an Erasable Programmable Read-Only Memory (EPROM) device, an Electrically Erasable programmable Read-only Memory (EEPROM) device, a flash memory device, a Phase Change Random Access Memory (PRAM) device, a Resistance Random Access memory (RRAM) device, an Nano Floating Gate Memory (NFGM) device, a Polymer Random Access Memory (PoRAM) device, a Magnetic Random Access Memory (MRAM), a Ferroelectric Random Access Memory (FRAM) device, and the like, and/or a volatile memory device such as a Dynamic Random Access Memorial (DRAM) device, a Static Random access Memory (SRAM) device, mobile DRAM device, or the like.

The storage device may include a solid-state drive (SSD), a hard disk drive (HDD), a CD-ROM, and the like.

The input/output device may include input means such as a keyboard, keypad, touchpad, touchscreen, mouse, etc., and output means such as a speaker, printer, or the like. According to an embodiment, the display devices 1210 and 1220 may be parts of or coupled to the input/output device.

The power supply may supply power necessary for the operation of the electronic device 1000. For example, the power supply may be a power management integrated circuit (PMIC). According to an embodiment, the power supply may supply power to the display device 1060.

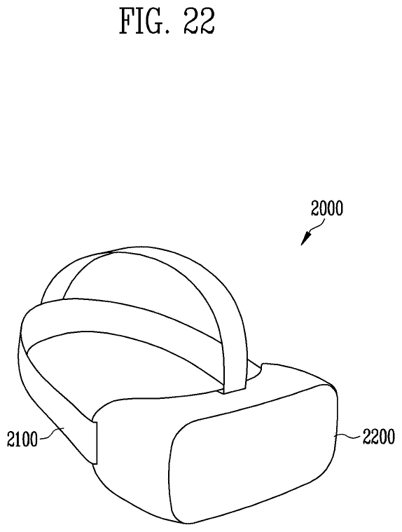

FIG. 22 is a perspective view illustrating an example of which the electronic device of FIG. 21 is applied.

Referring to FIG. 22, the electronic device 1000 of FIG. 21 may be applied to the head-mounted display device 2000. The head-mounted display device 2000 may be a wearable electronic device that may be worn on the user's head.

The head-mounted display device 2000 may include a head-mounted band 2100 and a display device storage case 2200. The head mounted band 2100 may be connected to the display device storage case 2200. The head mounted band 2100 may include a horizontal band and/or a vertical band for securing the head mounted display device 2000 to the user's head. The horizontal band may be configured to surround a side of the user's head, and the vertical band may be configured so as to surround an upper portion of the user's head. However, embodiments are not limited thereto. For example, the head mounted band 2100 may be implemented in the form of an eyeglass frame, a helmet, or the like.

The display device storage case 2200 may store the first and second display devices 1210 and 1220 of FIG. 21. The display device storage case 2200 may further store the processor 1100 of FIG. 21.

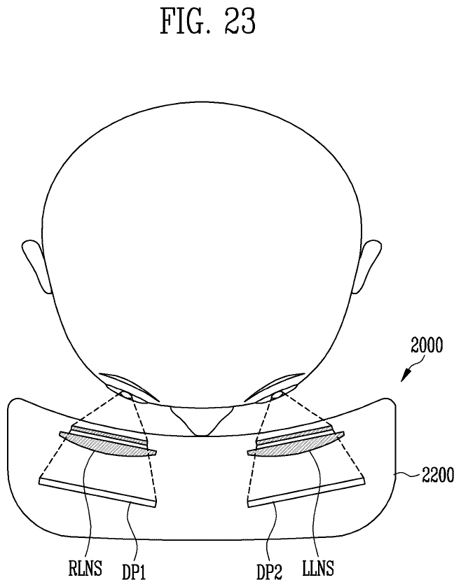

FIG. 23 is a view illustrating the head-mounted display device 2000 worn by the user of FIG. 22.

Referring to FIG. 23, a first display panel DP1 of the first display device 1210 and a second display panel DP2 of the second display device 1220 are disposed in the head-mounted display device 2000. The head-mounted display device 2000 may further include one or more lenses LLNS and RLNS positioned to be in front of the user's eyes.

In the display device storage case 2200, right eye lens RLNS may be disposed between the first display panel DP1 and the right eye of the user. In the display device storage case 2200, left eye lens LLNS may be disposed between the second display panel DP2 and the left eye of the user.

The image output from the first display panel DP1 may be shown to the right eye of the user through the right eye lens RLNS. The right eye lens RLNS may refract light from the first display panel DP1 toward the right eye of the user. The right eye lens RLNS may perform an optical function for adjusting a viewing distance between the first display panel DP1 and the right eye of the user.

The image output from the second display panel DP2 may be shown to the left eye of the user through the left eye lens LLNS. The left eye lens LLNS may refract light from the second display panel DP2 toward the left eye of the user. The left eye lens LLNS may perform an optical function for adjusting the viewing distance between the second display panel DP2 and the left eye of the user.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-regions having different optical properties. In this case, each display panel outputs images respectively corresponding to the sub-areas of the multi-channel lens, and the output images may be respectively shown to the user through the corresponding sub-areas.

However, the example to which the display device 100 is applied is not limited to those described above. According to an embodiment, the display device 100 is applicable to various electronic devices.

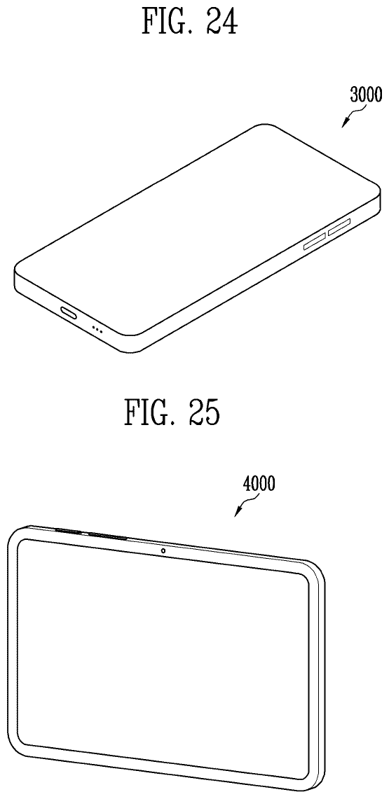

FIGS. 24 to 28 are schematic diagrams illustrating application examples of the display device 100 according to an embodiment.

In an embodiment, referring to FIG. 24, the display device 100 may be applied to the smartphone 3000.

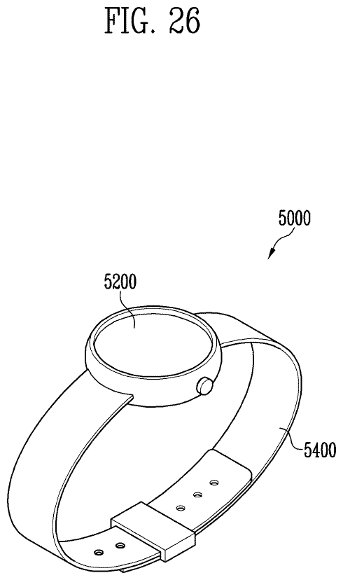

In an embodiment, referring to FIG. 25, the display device 100 may be applied to a tablet personal computer (PC) 4000.

In an embodiment, referring to FIG. 26, the display device 100 may be applied to a wearable device, for example, the display device 100 may be applied to a smart watch 5000.

The smart watch 5000 may be a wearable electronic device. For example, the smart watch 5000 may include a watch display portion 5200 and a strap portion 5400 connected to the watch display portion 5200, and have a structure in which the strap portion 5400 is mounted on a wrist of the user. Here, the display device 100 is applied to the watch display portion 5200, so that image data including time information may be provided to the user.

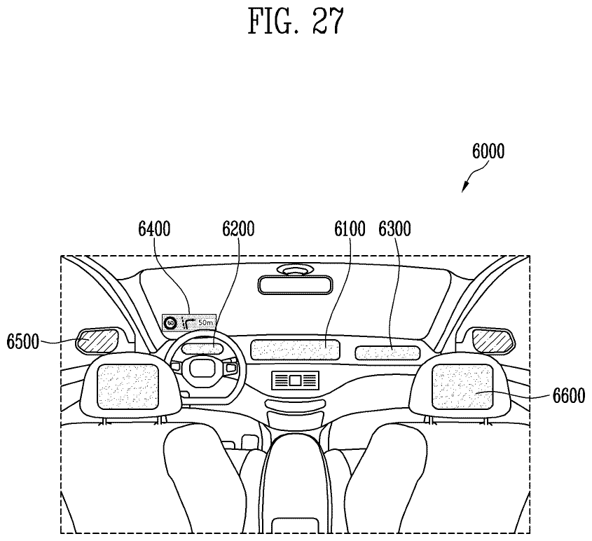

In an embodiment, referring to FIG. 27, the display device 100 may be applied to an automatic display system 6000.

The automatic display system 6000 may include a computing system provided inside and/or outside the vehicle to provide image data.

For example, the display device 100 may be applied to at least one of an infotainment panel 6100, a cluster 6200, a co-driver display 6300, a head-up display 6400, a side mirror display 6500, and a rear seat display 6600 provided in a vehicle.

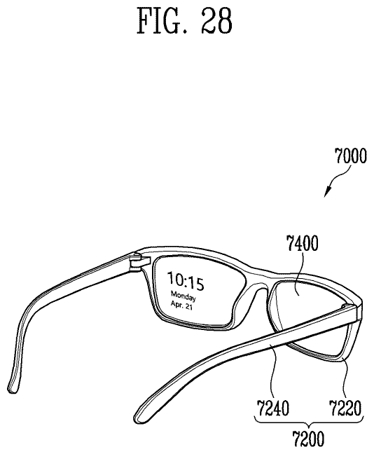

In an embodiment, referring to FIG. 28, the display device 100 may be applied to a smart glass 7000.

The smart glass 7000 may be a wearable electronic device that is wearable on the user's head. For example, the smart glass 7000 may be a wearable device for augmented reality.

The smart glass 7000 may include a frame 7200 and a lens portion 7400. The frame 7200 may include a housing 7220 that supports the lens portion 7400 and a leg portion 7240 for wearing by the user. The leg portion 7240 is connected to the housing 7220 via a hinge, and may be folded or unfolded relative to the housing 7220.

The frame 7200 may include a battery, a touch pad, a microphone, a camera, and the like. In addition, a projector that outputs light, a processor that controls an optical signal, and the like may be embedded in the frame 7200.

The lens portion 7400 may include an optical member that transmits or reflects light. For example, the lens portion 7400 may include glass, a transparent synthetic resin, or the like.

In order for the user's eyes to recognize visual information, the inner surface of the lens portion 7400 may reflect an image received from a projector in the frame 7200. An “inner surface” of the lens portion 7400 refers to the surface of the lens portion 7400 facing the user's eye. For example, the user may recognize visual information such as a time and a date displayed on the lens portion 7400. In this case, the projector and/or the lens portion 7400 may be a type of display device. The display device 100 may be applied to the projector and/or the lens portion 7400.

As discussed above, although the present disclosure has been described with reference to example embodiments, it will be understood by those skilled in the art or those skilled in the relevant art that various modifications and changes may be made to the present disclosure without departing from the spirit and technical scope of the present disclosure as set forth in the following claims.

Therefore, the technical scope of the present disclosure should not be limited to the contents described in the detailed description of the specification, but should be determined by the claims.

An aspect of the present disclosure is to provide a display device in which a process procedure may be simplified and a process cost may be reduced, a method of manufacturing the display device, and an electronic device.

An aspect of the present disclosure is to provide a display device in which a risk that an unintended structure is excessively formed may be reduced, and operation reliability characteristics may be improved, a method of manufacturing the display device, and an electronic device.

What is claimed is:

1. A display device comprising:
a light-emitting element including an anode electrode disposed on a substrate, a light-emitting structure electrically connected to the anode electrode, and a cathode electrode electrically connected to the light-emitting structure; and
a cover layer disposed on the anode electrode,
wherein the anode electrode includes a first end, the cover layer includes a second end, and the first end and the second end have side surfaces in parallel planes.

2. The display device of claim 1, further comprising a lower structure disposed between the substrate and the light-emitting element and covered by the anode electrode.

3. The display device of claim 2, further comprising:
sub-pixels each including the light-emitting element and the cover layer; and
a pixel circuit disposed on the substrate and electrically connected to the anode electrode,
wherein the lower structure includes a conductive layer, a reflective layer on the conductive layer, and a step-forming layer on the reflective layer,
wherein the conductive layer is electrically connected to the pixel circuit, and
wherein the reflective layer reflects light in a display direction of the display device, and
wherein the step-forming layer has different thicknesses in different sub-pixels.

4. The display device of claim 3, wherein the anode electrode covers a side surface of each of the conductive layer, the reflective layer, and the step-forming layer, and
wherein the anode electrode disposed on an upper surface of the step-forming layer covers an entire upper surface of the step-forming layer such that the anode electrode is between the light-emitting structure and a top surface of the lower structure.

5. The display device of claim 4, wherein the cover layer covers a first portion of the anode electrode that includes a side surface of the lower structure but does not cover a second portion of the anode electrode that is disposed on the top surface of the lower structure.

6. The display device of claim 5, further comprising:
an insulating layer covering a portion of the cover layer on the side surface of the lower structure while not covering the second portion of the anode electrode, and including an inorganic material; and
an intermediate layer disposed adjacent to the lower structure to offset a step formed by the lower structure.

7. The display device of claim 6,
wherein the anode electrode includes indium tin oxide (ITO) or titanium nitride (TiN),
wherein the insulating layer includes silicon nitride (SixNy), and
wherein the intermediate layer includes an oxide material.

8. The display device of claim 1, wherein the cover layer is in contact with the anode electrode but not with a side surface of the first end of the anode electrode,
wherein the side surface of the first end of the anode electrode is coplanar with a side surface of the second end of the cover layer.

9. The display device of claim 8, wherein the cover layer includes an inorganic oxide, and
wherein the cover layer has a thickness in a range of 500 to 1000 Angstroms.

10. A method of manufacturing a display device, the method comprising:
forming a base anode electrode on a substrate and on a lower structure on the substrate;
patterning a cover layer covering the base anode electrode and removing part of the cover layer to expose at least a portion of the base anode electrode;
forming an anode electrode by removing at least the portion of the base anode electrode using the cover layer as an etch mask; and
removing a residue portion that forms at an end portion of the cover layer, the residue portion including a same material as the base anode electrode.

11. The method of claim 10, further comprising patterning the lower structure including a conductive layer, a reflective layer on the conductive layer, and a step-forming layer on the reflective layer,
wherein the forming of the base anode electrode includes covering a side surface of the lower structure by the base anode electrode, and
wherein the lower structure has a trapezoidal cross-section.

12. The method of claim 10, wherein the patterning of the cover layer includes:
forming a base cover layer covering the anode electrode and including an oxide;
patterning a photoresist layer on the base cover layer; and
dry etching the base cover layer using the photoresist layer as an etching mask,
wherein the base cover layer is formed by an atomic layer deposition (ALD) process.

13. The method of claim 12, further comprising, after patterning the cover layer, performing an ashing process to remove the photoresist layer,
wherein the patterning of the cover layer includes:
forming a side end of the cover layer; and
exposing at least a portion of the base anode electrode with the cover layer in place.

14. The method of claim 10, wherein, in the forming of the anode electrode, an upper surface of the cover layer that is used as a hard etching mask for the anode electrode is exposed.

15. The method of claim 10, wherein the residue portion includes a same material as the anode electrode, and
covers a side surface at an end of the cover layer.

16. The method of claim 15, wherein a thickness of the residue portion is determined based on a thickness of the cover layer used as a hard etching mask for the anode electrode.

17. The method of claim 10, further comprising fixing the substrate by the chuck while forming the anode electrode,
wherein the cover layer includes an inorganic oxide, and
wherein the chuck is heated about to 80 degrees.

18. The method of claim 10, wherein in the removing of the residue portion, a wet cleaning method using Diluted HF (DHF) is performed, and
wherein the residue portion has a first etch ratio for the cover layer and a second etch ratio smaller than the first etch ratio for the anode electrode.

19. The method of claim 10, further comprising, forming an insulating layer covering a side end of each of the cover layer and the anode electrode; and
after forming a base intermediate layer, polishing the base intermediate layer to a polishing stopper plane formed in a region where the uppermost surface of the insulating layer is exposed to form an intermediate layer flattening lower steps.

20. An electronic device, comprising:
a processor providing input image data;
a display device displaying an image based on the input image data; and
a power supply supplying power to the display device,
wherein the display device includes:
a light-emitting element including an anode electrode disposed on a substrate, a light-emitting structure electrically connected to the anode electrode, and a cathode electrode electrically connected to the light-emitting structure; and
a cover layer disposed on the anode electrode,
wherein the anode electrode includes a first end, the cover layer includes a second end, and the first end and the second end have side surfaces in parallel planes.
